(19) United States
(12) Patent Application Publication
(10) Pub. No.: US 2026/0291437 A1
(43) Pub. Date: Sep. 24, 2026

(54) Piezoelectric Vibration Device

(71) Applicant: Daishinku Corporation, Hyogo (JP)

(72) Inventors: Kazuya Fujino, Kakogawa-shi (JP); Manabu Ohnishi, Kakogawa-shi (JP)

(73) Assignee: Daishinku Corporation, Hyogo (JP)

(21) Appl. No.: 19/168,806

(22) PCT Filed: Mar. 18, 2024
(86) PCT No.: PCT/JP2024/010432

§ 371 Date: Sep. 24, 2025

(30) Foreign Application Priority Data
Mar. 27, 2023 (JP) 2023-049375

(51) Int. Cl. H03B 5/32

(52) U.S. Cl. CPC H03B 5/323

(57) ABSTRACT

Piezoelectric vibration device in which during reflow leakage of molten flux and molten solder from the device can be curtailed. The piezoelectric vibration device includes a substrate on the upper surface of which a piezoelectric vibrator and an electronic component are mounted, in a sealing resin polymer molded to cover them. Formed on the exterior bottom surface of the piezoelectric vibrator are external connection terminals that are joined via solder to piezoelectric vibrator mounting pads formed on the substrate upper surface. In plan view, the sides of the sealing polymer and the sides of the piezoelectric vibrator oppose each other, wherein among the distances La-Ld between opposing sealing-polymer and piezoelectric-vibrator sides, the distance Ld that is the minimum is at least 10% of the sealing-polymer dimension lengthwise along the minimum distance Ld.

### TECHNICAL FIELD

The present invention relates to a piezoelectric vibration device that includes a substrate, a piezoelectric vibrator and an electronic component mounted to one main surface of the substrate, and a sealing resin molded on the one main surface side of the substrate so as to cover the piezoelectric vibrator and the electronic component.

### BACKGROUND ART

Examples of a piezoelectric vibration device include the following piezoelectric vibration device disclosed in PTL 1. The disclosed piezoelectric vibration device includes a substrate, a piezoelectric vibrator and an electronic component mounted to one main surface of the substrate, and a sealing resin molded on the one main surface side of the substrate so as to cover the piezoelectric vibrator and the electronic component. A plurality of external connection terminals are formed on an outer bottom surface of the piezoelectric vibrator, a plurality of piezoelectric vibrator mounting pads that respectively correspond to the plurality of external connection terminals are formed on the one main surface of the substrate, and the plurality of piezoelectric vibrator mounting pads are each formed in a substantially rectangular shape in plan view. The plurality of external connection terminals formed on the outer bottom surface of the piezoelectric vibrator are each joined via solder to a corresponding piezoelectric vibrator mounting pad among the plurality of piezoelectric vibrator mounting pads formed on the one surface of the substrate.

### PRECEDENT TECHNICAL LITERATURE

### Patent Literature

Patent Literature 1: JP 2007-173431A

### SUMMARY OF INVENTION

### Technical Problem

Incidentally, in the manufacturing process of the above piezoelectric vibration device, flux cleaning is performed after the plurality of external connection terminals of the piezoelectric vibrator are each mounted to the corresponding piezoelectric vibrator mounting pad among the plurality of piezoelectric vibrator mounting pads on the substrate using solder. The flux cleaning is performed using spray/shower cleaning, for example, but flux on the back surface (lower surface) of the piezoelectric vibrator may not be completely removed. Thus, there is a problem in that molten flux or molten solder leak out of the sealing resin during reflow that is performed after the flux cleaning.

In view of the above problem, an object of the present invention is to provide a piezoelectric vibration device that is able to suppress leakage of molten flux and molten solder from the piezoelectric vibration device during reflow.

### Solution to Problem

In order to achieve the above object, a piezoelectric vibration device according to the present invention is a piezoelectric vibration device including a substrate, a piezoelectric vibrator and an electronic component mounted to one main surface of the substrate, and a sealing resin molded on the one main surface side of the substrate so as to cover the piezoelectric vibrator and the electronic component, in which, on an outer bottom surface of the piezoelectric vibrator, a plurality of external connection terminals are formed in a peripheral portion of the outer bottom surface, on the one main surface of the substrate, a plurality of piezoelectric vibrator mounting pads respectively corresponding to the plurality of external connection terminals are formed, each of the plurality of external connection terminals is joined via solder to a corresponding piezoelectric vibrator mounting pad among the plurality of piezoelectric vibrator mounting pads, and, in plan view, sides constituting outer lateral faces of the sealing resin respectively oppose sides constituting lateral faces of the piezoelectric vibrator, and a shortest distance among the distances between the opposing sides of the outer lateral faces of the sealing resin and the lateral faces of the piezoelectric vibrator is 7.8% or more of a dimension of the sealing resin in a length direction of the shortest distance.

With this configuration, the shortest distance, in plan view, among the distances between the opposing sides of the outer lateral faces of the sealing resin and the lateral faces of the piezoelectric vibrator is 7.8% or more of the dimension of the sealing resin in the length direction of the shortest distance, and thus a distance effective in suppressing leakage of flux or solder from the sealing resin during reflow can be provided between the side of the outer lateral face of the sealing resin and the side of the lateral face of the piezoelectric vibrator where the distance is shortest. Leakage of molten flux or molten solder from the piezoelectric vibration device during reflow can thereby be suppressed.

Also, a configuration may be adopted in which the substrate has a substantially rectangular shape in plan view, the piezoelectric vibrator has a substantially rectangular shape in plan view, and the piezoelectric vibrator is mounted to the one main surface of the substrate such that short sides of the piezoelectric vibrator are orthogonal to short sides of the substrate.

With this configuration, the long sides of the substrate having a rectangular shape in plan view are more likely to warp than the short sides, but warping of the substrate can be suppressed, by mounting the piezoelectric vibrator to the substrate such that the short sides of the piezoelectric vibrator are orthogonal to the short sides of the substrate. Thus, during reflow, movement of molten flux or molten solder flowing in the direction of the outer lateral faces of the sealing resin can be suppressed, and leakage of molten flux or molten solder from the piezoelectric vibration device can be further suppressed.

Also, a configuration may be adopted in which the plurality of piezoelectric vibrator mounting pads are four piezoelectric vibrator mounting pads, and are respectively disposed in four corners of a substantially rectangular region that includes an overlapping region, on the one main surface of the substrate, where the one main surface and the piezoelectric vibrator overlap each other in plan view and surrounds the overlapping region, each of the plurality of piezoelectric vibrator mounting pads is substantially L-shaped in plan view, and each of the piezoelectric vibrator mounting pads bends such that an edge nearest a center of the overlapping region, among the edges of the piezoelectric vibrator mounting pad, extends away from the center in plan view.

With this configuration, each of the four piezoelectric vibrator mounting pads is substantially L-shaped in plan view, and bends such that the edge thereof nearest the center of the overlapping region extends away from the center in plan view, thus enabling the inner portion surrounded by the four piezoelectric vibrator mounting pads where molten flux and molten solder accumulate to be enlarged, compared with the case where the four piezoelectric vibrator mounting pads are each substantially rectangular in plan view. Leakage of molten flux or molten solder from the piezoelectric vibration device during reflow can thereby be further suppressed.

Also, a configuration may be adopted in which each of the plurality of piezoelectric vibrator mounting pads is located inside a recessed part provided in the one main surface of the substrate to correspond to the piezoelectric vibrator mounting pad, and disposed such that there is a gap between the opposing lateral faces of the piezoelectric vibrator mounting pad and the recessed part.

With this configuration, molten flux and molten solder can be pooled in the gap between the lateral faces of the piezoelectric vibrator mounting pad and the lateral faces of the recessed part during reflow, and thus leakage of molten flux or molten solder from the piezoelectric vibration device can be further suppressed.

### Advantageous Effects of Invention

According to the present invention, the shortest distance, in plan view, among the distances between the opposing sides of the outer lateral faces of the sealing resin and the lateral faces of the piezoelectric vibrator is 7.8% or more of the dimension of the sealing resin in the length direction of the shortest distance, and thus a distance effective in suppressing leakage of flux or solder from the sealing resin during reflow can be provided between the side of the outer lateral face of the sealing resin and the side of the lateral face of the piezoelectric vibrator where the distance is shortest. Leakage of molten flux or molten solder from the piezoelectric vibration device during reflow can thereby be suppressed.

### BRIEF DESCRIPTION OF DRAWINGS

FIG. 1: A schematic plan view of the upper surface side of a piezoelectric vibration device excluding a sealing resin according to a first embodiment of the present invention.

FIG. 2: A schematic plan view of the lower surface side of the piezoelectric vibration device in FIG. 1 (substrate in FIG. 1).

FIG. 3: A schematic cross-sectional view of the piezoelectric vibration device taken along line A-A of FIG. 1 in which the sealing resin is added.

FIG. 4: A schematic plan view of the upper surface side of a piezoelectric vibrator in FIG. 1 (first sealing member included in piezoelectric vibrator of FIG. 1).

FIG. 5: A schematic plan view of the lower surface side of the first sealing member included in the piezoelectric vibrator of FIG. 1.

FIG. 6: A schematic plan view of the upper surface side of a piezoelectric diaphragm included in the piezoelectric vibrator of FIG. 1.

FIG. 7: A schematic plan view of the lower surface side of the piezoelectric diaphragm included in the piezoelectric vibrator of FIG. 1.

FIG. 8: A schematic plan view of the upper surface side of a second sealing member included in the piezoelectric vibrator of FIG. 1.

FIG. 9: A schematic plan view of the lower surface side of the piezoelectric vibrator in FIG. 1 (second sealing member included in piezoelectric vibrator of FIG. 1).

FIG. 10: A schematic plan view of the upper surface side of the substrate in FIG. 1.

FIG. 11: A schematic plan view for describing the positional relationship in plan view between the piezoelectric vibrator of FIGS. 1 and 3 and the sealing resin of FIG. 3.

FIG. 12: Descriptive diagrams for describing similarities of the shapes of piezoelectric vibrator mounting pads in FIG. 10 to external connection terminals in FIG. 9.

FIG. 13: Descriptive diagrams for describing one variation of the shapes of the external connection terminals and the piezoelectric vibrator mounting pads.

FIG. 14: Descriptive diagrams for describing another variation of the shapes of the external connection terminals and the piezoelectric vibrator mounting pads.

FIG. 15: A schematic cross-sectional view (sectional front view) of a piezoelectric vibration device according to a second embodiment of the present invention.

FIG. 16: A schematic plan view of the upper surface side of the piezoelectric vibration device excluding a sealing resin according to the second embodiment.

FIG. 17: A schematic plan view in which the substrate is rendered visible from the upper surface side of the piezoelectric vibration device in FIG. 16.

FIG. 18: A schematic cross-sectional view (sectional front view) of a piezoelectric vibration device according to a third embodiment of the present invention.

FIG. 19: A schematic plan view of the upper surface side of the piezoelectric vibration device excluding a sealing resin according to the third embodiment.

FIG. 20: A schematic plan view in which the substrate is rendered visible from the upper surface side of the piezoelectric vibration device in FIG. 19.

FIG. 21: A schematic cross-sectional view (sectional front view) of a piezoelectric vibration device according to a fourth embodiment of the present invention.

FIG. 22: A schematic plan view of the upper surface side of a piezoelectric vibration device excluding a sealing resin according to the fourth embodiment.

FIG. 23: A schematic plan view in which the substrate is rendered visible from the upper surface side of the piezoelectric vibration device in FIG. 22.

FIG. 24: A schematic cross-sectional view (sectional front view) of a piezoelectric vibration device according to a fifth embodiment of the present invention.

FIG. 25: A schematic plan view of the upper surface side of the piezoelectric vibration device excluding a sealing resin according to the fifth embodiment.

### MODES OF EMBODYING INVENTION

### First Embodying Mode

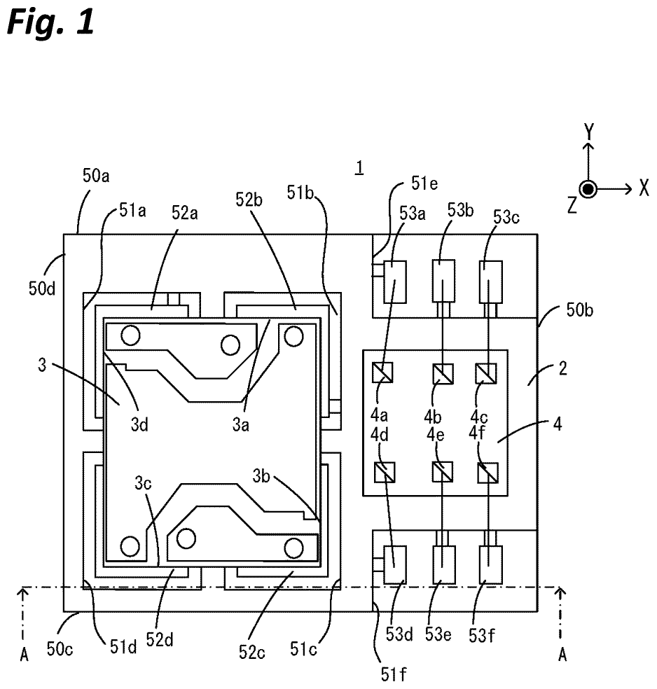

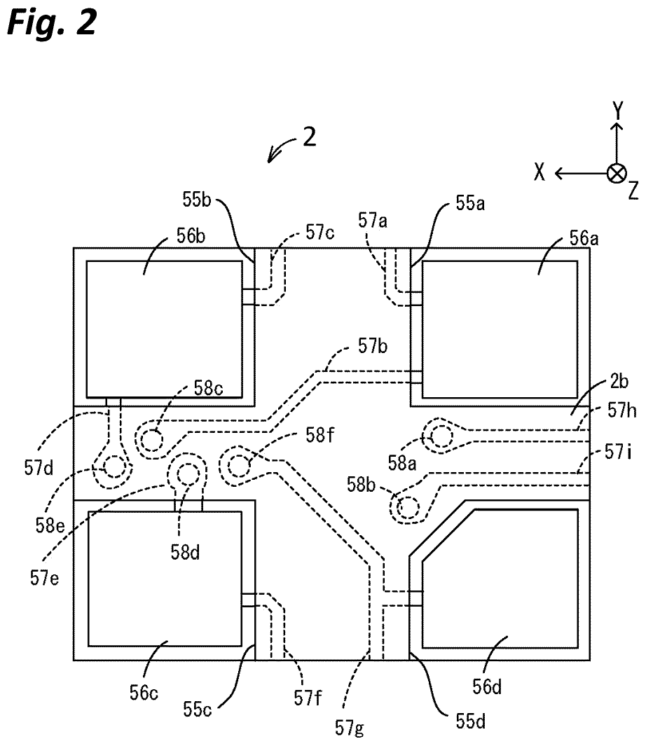

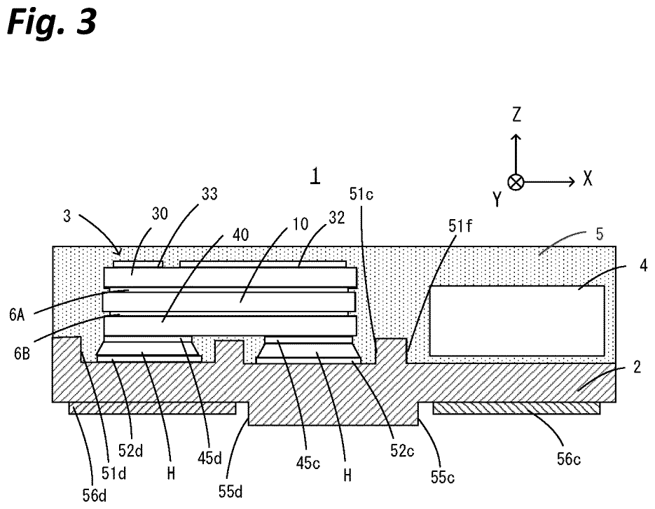

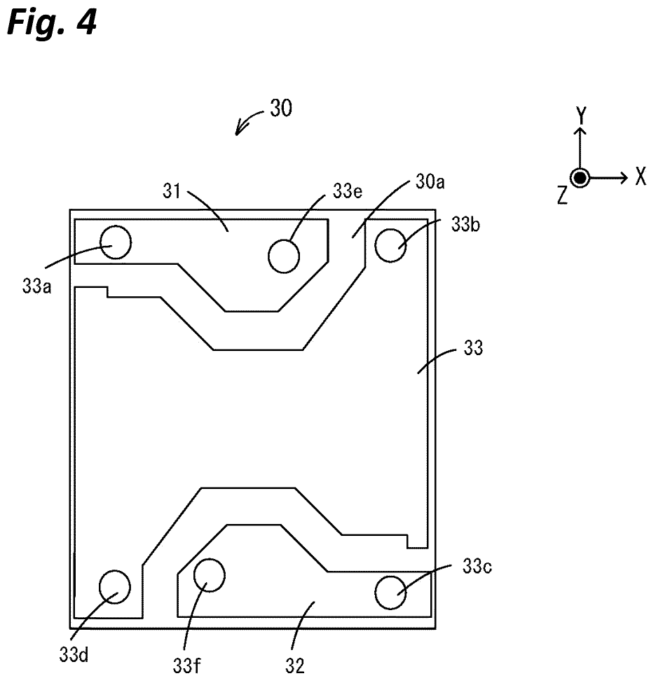

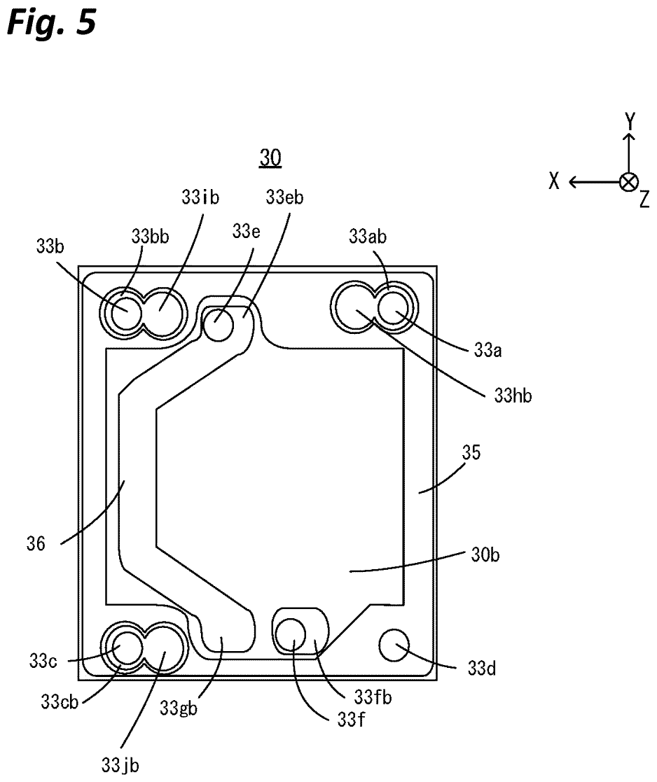

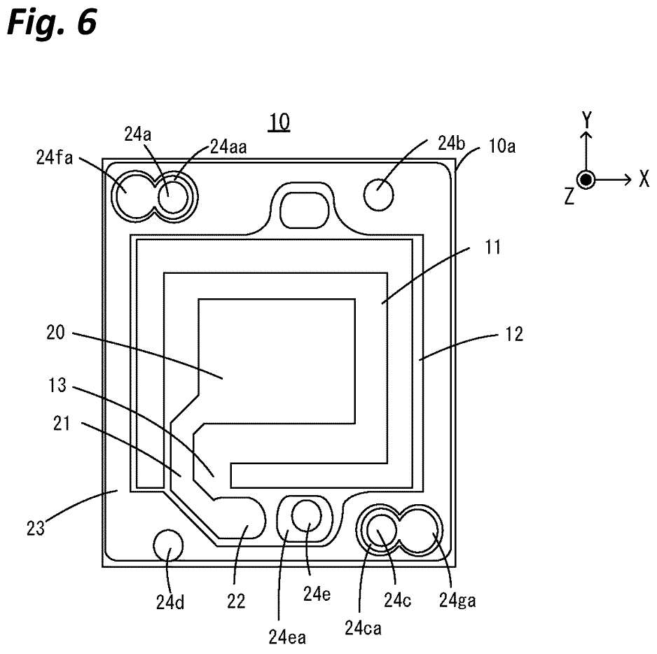

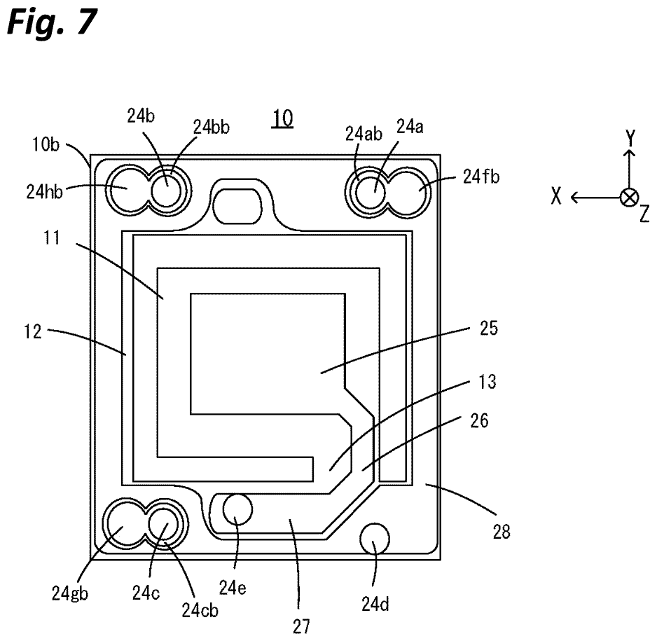

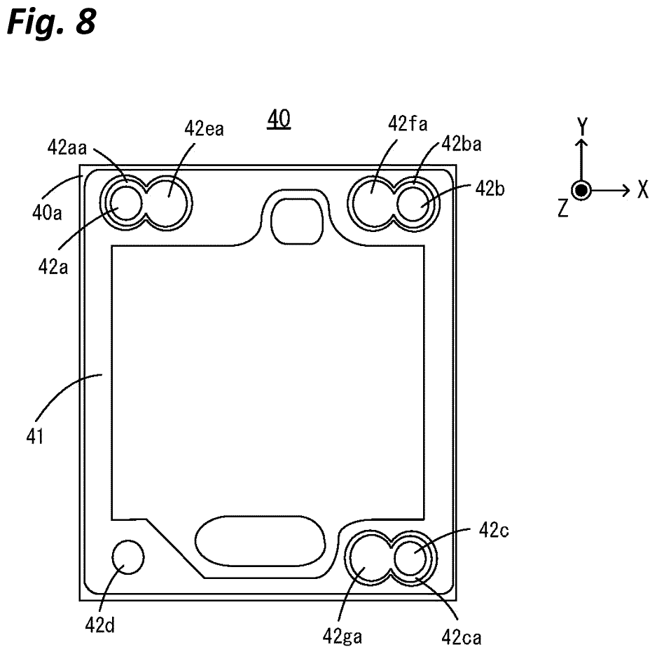

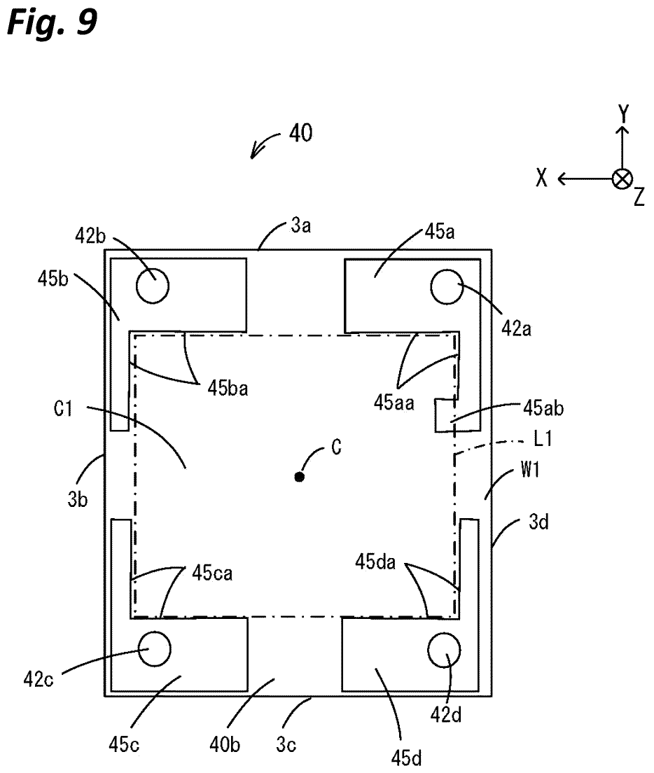

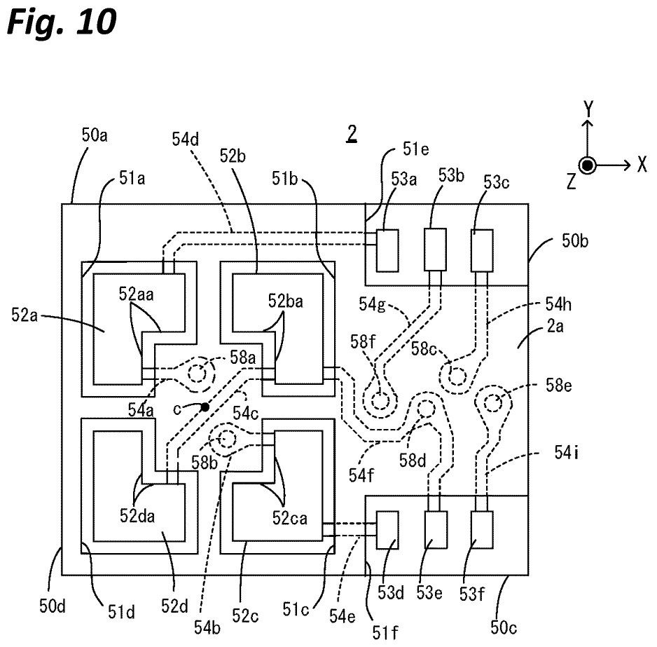

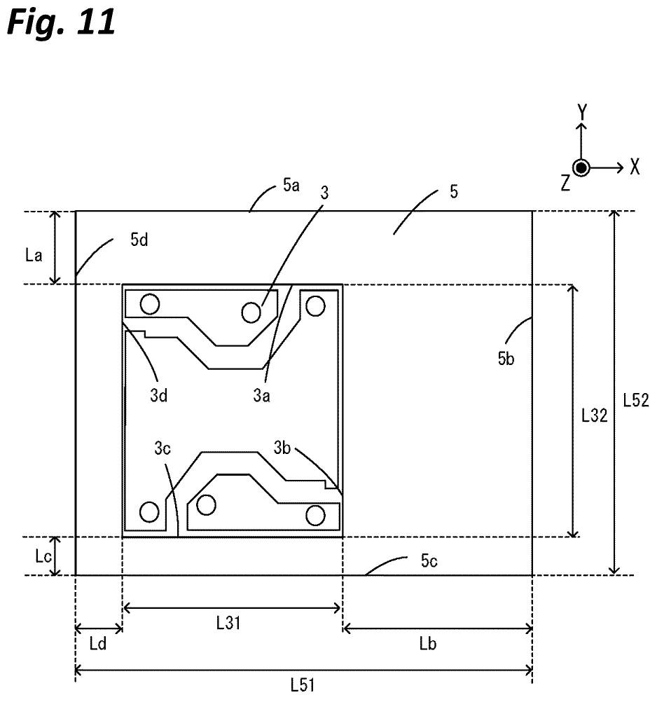

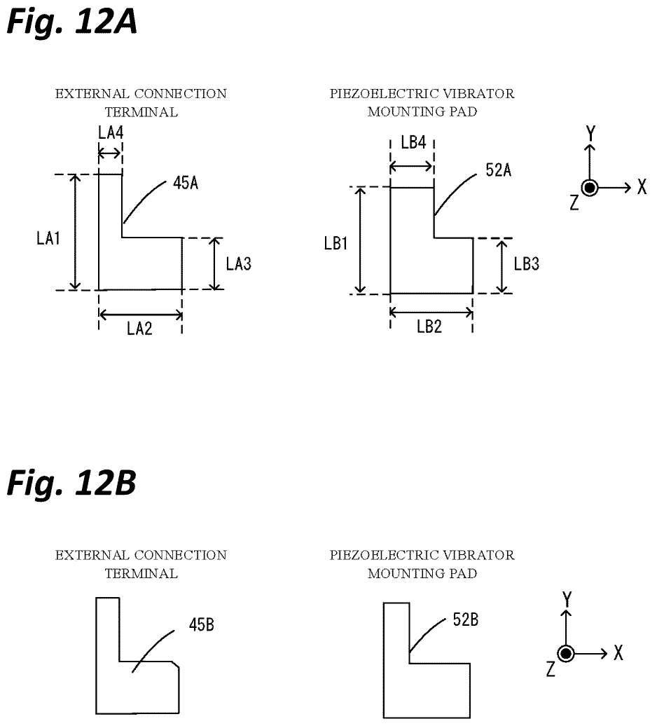

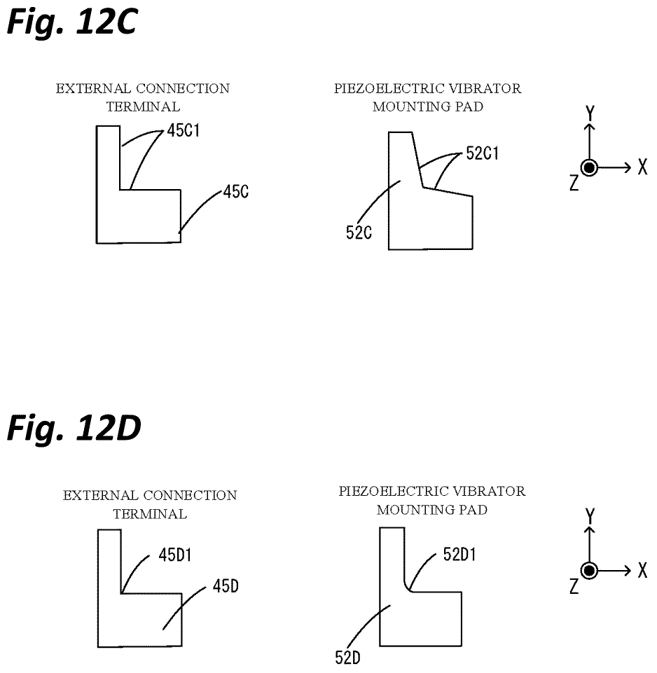

A piezoelectric vibration device according to a first embodiment of the present invention will now be described with reference to FIGS. 1 to 11. FIG. 1 is a schematic plan view of the upper surface side of a piezoelectric vibration device 1 excluding a sealing resin 5 according to the first embodiment of the present invention. FIG. 2 is a schematic plan view of the lower surface side (substrate 2 in FIG. 1) of the piezoelectric vibration device 1 in FIG. 1. FIG. 3 is a schematic cross-sectional view of the piezoelectric vibration device taken along line A-A of FIG. 1 in which the sealing resin 5 is added. FIG. 4 is a schematic plan view of the upper surface side of a piezoelectric vibrator 3 in FIG. 1 (first sealing member 30 included in piezoelectric vibrator 3 of FIG. 1). FIG. 5 is a schematic plan view of the lower surface side of the first sealing member 30 included in the piezoelectric vibrator 3 of FIG. 1. FIG. 6 is a schematic plan view of the upper surface side of a piezoelectric diaphragm 10 included in the piezoelectric vibrator 3 of FIG. 1. FIG. 7 is a schematic plan view of the lower surface side of the piezoelectric diaphragm 10 included in the piezoelectric vibrator 3 of FIG. 1. FIG. 8 is a schematic plan view of the upper surface side of a second sealing member 40 included in the piezoelectric vibrator 3 of FIG. 1. FIG. 9 is a schematic plan view of the lower surface side of the piezoelectric vibrator 3 in FIG. 1 (second sealing member 40 included in piezoelectric vibrator 3 of FIG. 1). FIG. 10 is a schematic plan view of the upper surface side of the substrate 2 in FIG. 1. FIG. 11 is a schematic plan view for describing the relationship in plan view between the piezoelectric vibrator 3 of FIGS. 1 and 3 and the sealing resin 5 of FIG. 3. FIG. 12 includes descriptive diagrams for describing similarities of the shapes of first to fourth piezoelectric vibrator mounting pads 52a to 52d in FIG. 10 to first to fourth external connection terminals 45a to 45d in FIG. 9. Note that the X axis, the Y axis, and the Z axis of each of FIGS. 1 to 12 are the same set of coordinate axes. Also, the X axis and Y axis of the drawings represent the horizontal direction and the Z axis represents the vertical direction.

As shown in FIGS. 1 to 3, the piezoelectric vibration device 1 includes the substrate (corresponds to “substrate” of the present invention) 2, the piezoelectric vibrator (corresponds to “piezoelectric vibrator” of the present invention) 3 and an electronic component (corresponds to “electronic component” of the present invention) 4 mounted to an upper surface (corresponds to “one main surface” of the present invention) 2a of the substrate 2, and the sealing resin (corresponds to “sealing resin” of the present invention) 5 molded on the upper surface 2a side of the substrate 2 so as to cover the piezoelectric vibrator 3 and the electronic component 4.

As shown in FIG. 3, the piezoelectric vibrator 3 includes the piezoelectric diaphragm 10, the first sealing member 30, and the second sealing member 40. In the piezoelectric vibrator 3, a substantially rectangular parallelepiped package having a sandwich structure is constituted, by the piezoelectric diaphragm 10 being joined to the first sealing member 30 and the piezoelectric diaphragm 10 being joined to the second sealing member 40. That is, in the piezoelectric vibrator 3, an internal space (cavity) C1 of the package is formed by the first sealing member 30 and the second sealing member 40 being respectively joined to the two main surfaces of the piezoelectric diaphragm 10, and a vibration part 11 is airtightly sealed in this internal space C1.

As shown in FIG. 1, the piezoelectric vibrator 3 has a substantially rectangular shape in plan view, in which a first side 3a and a third side 3c opposing each other are the short sides, and a second side 3b and a fourth side 3d opposing each other are the long sides. Note that, hereinafter, the first side 3a and the third side 3c will be referred to as first short side 3a and third short side 3c, and the second side 3b and the fourth side 3d will be referred to as second long side 3b and fourth long side 3d.

The piezoelectric vibrator 3 is mounted to the later-described upper surface 2a of the substrate 2, such that the later-described first to fourth external connection terminals 45a to 45d formed on the outer bottom surface of the piezoelectric vibrator 3 (lower surface of piezoelectric vibrator 3; lower surface 40b of second sealing member 40) are electrically joined to the later-described first to fourth piezoelectric vibrator mounting pads 52a to 52d formed on the upper surface 2a of the substrate 2. As shown in FIG. 1, the piezoelectric vibrator 3 is mounted to the upper surface 2a of the substrate 2, such that, in plan view, the first short side 3a and third short side 3c of the piezoelectric vibrator 3 are substantially orthogonal to the later-described second short side 50b and fourth short side 50d of the substrate 2.

Next, the members constituting the piezoelectric vibrator 3, namely, the piezoelectric diaphragm 10, the first sealing member 30, and the second sealing member 40, will be described in order.

First, the piezoelectric diaphragm 10 will be described with reference to FIGS. 6 and 7.

The piezoelectric diaphragm 10 is a piezoelectric substrate made of quartz crystal, and an upper surface 10a and a lower surface 10b are each formed as a flat smooth surface (mirror finishing). In the present embodiment, an AT-cut quartz crystal plate that vibrates in thickness-shear mode is used as the piezoelectric diaphragm 10.

The piezoelectric diaphragm 10 has the vibration part 11 formed in a substantially rectangular shape, an outer frame part 12 that surrounds the vibration part 11 with a space therebetween and is thicker than the vibration part 11, and a coupling part 13 that couples the vibration part 11 to the outer frame part 12. That is, the piezoelectric diaphragm 10 has a configuration in which the vibration part 11, the outer frame part 12, and the coupling part 13 are integrally provided.

A first excitation electrode 20 is formed in a portion of the vibration part 11 on the upper surface 10a of the piezoelectric diaphragm 10. Also, a second excitation electrode 25 is formed in a portion of the vibration part 11 on the lower surface 10b of the piezoelectric diaphragm 10.

A first lead wiring 21 for connecting the first excitation electrode 20 to the first external connection terminal 45a is formed on the upper surface 10a of the piezoelectric diaphragm 10. Also, a first connection joining pattern 22 is formed in a portion of the outer frame part 12 on the upper surface 10a of the piezoelectric diaphragm 10. The first lead wiring 21 is led out from the first excitation electrode 20 on the upper surface 10a of the piezoelectric diaphragm 10 and connected to the first connection joining pattern 22 via the coupling part 13.

A second lead wiring 26 for connecting the second excitation electrode 25 to the third external connection terminal 45c is formed on the lower surface 10b of the piezoelectric diaphragm 10. Also, a second connection joining pattern 27 is formed in a portion of the outer frame part 12 on the lower surface 10b of the piezoelectric diaphragm 10. The second lead wiring 26 is led out from the second excitation electrode 25 on the lower surface 10b of the piezoelectric diaphragm 10 and connected to the second connection joining pattern 27 via the coupling part 13.

A first vibration-side joining pattern 23 serving as a first vibration-side sealing part for joining the piezoelectric diaphragm 10 to the first sealing member 30 is provided on the upper surface 10a of the piezoelectric diaphragm 10. The first vibration-side joining pattern 23 is formed in an annular shape in plan view in a portion of the outer frame part 12 on the upper surface 10a of the piezoelectric diaphragm 10.

A second vibration-side joining pattern 28 serving as a second vibration-side sealing part for joining the piezoelectric diaphragm 10 to the second sealing member 40 is provided on the lower surface 10b of the piezoelectric diaphragm 10. The second vibration-side joining pattern 28 is formed in an annular shape in plan view in a portion of the outer frame part 12 on the lower surface 10b of the piezoelectric diaphragm 10.

Five through-hole electrodes (first to fifth through-hole electrodes 24a to 24e) that pass through between the upper surface 10a and the lower surface 10b and have a conductive material formed on the inner wall surface are formed in the piezoelectric diaphragm 10. Specifically, the first to fourth through-hole electrodes 24a to 24d are respectively provided in regions of the four corners (corner portions) of the outer frame part 12. The fifth through-hole electrode 24e is provided on the inner side of the first vibration-side joining pattern 23 and the second vibration-side joining pattern 28 of the outer frame part 12 in plan view.

On the upper surface 10a of the piezoelectric diaphragm 10, first and third upper surface-side connection joining patterns 24aa and 24ca that are electrically connected to the first and third through-hole electrodes 24a and 24c are formed on the periphery of the first and third through-hole electrodes 24a and 24c. Also, on the lower surface 10b of the piezoelectric diaphragm 10, first to third lower surface-side connection joining patterns 24ab to 24cb that are electrically connected to the first to third through-hole electrodes 24a to 24c are formed on the periphery of the first to third through-hole electrodes 24a to 24c. Note that the first vibration-side joining pattern 23 electrically connected to the second and fourth through-hole electrodes 24b and 24d is on the upper surface 10a of the piezoelectric diaphragm 10. Also, the second vibration-side joining pattern 28 electrically connected to the fourth through-hole electrode 24d is on the lower surface 10b of the piezoelectric diaphragm 10. On the upper surface 10a of the piezoelectric diaphragm 10, a fifth upper surface-side connection joining pattern 24ea that is electrically connected to the fifth through-hole electrode 24e is formed on the periphery of the fifth through-hole electrode 24e. Note that the second connection joining pattern 27 electrically connected to the fifth through-hole electrode 24e is on the lower surface 10b of the piezoelectric diaphragm 10.

Sixth and seventh upper surface-side connection joining patterns 24fa and 24ga that are electrically connected to the first and third upper surface-side connection joining patterns 24aa and 24ca are formed on the upper surface 10a of the piezoelectric diaphragm 10. Also, sixth, eighth, and seventh lower surface-side connection joining patterns 24fb, 24hb, and 24gb that are electrically connected to the first to third lower surface-side connection joining patterns 24ab to 24cb are formed on the lower surface 10b of the piezoelectric diaphragm 10.

Next, the first sealing member 30 will be described with reference to FIGS. 4 and 5.

The first sealing member 30 is a substantially rectangular parallelepiped substrate formed from a single quartz crystal plate, and the surface on the side joined to the piezoelectric diaphragm 10 is formed as a flat smooth surface (mirror finishing). In the present embodiment, an AT-cut quartz crystal plate is used as the first sealing member 30, as with the piezoelectric diaphragm 10.

As shown in FIG. 4, on an upper surface 30a of the first sealing member 30, which corresponds to the upper surface of the piezoelectric vibrator 3, wiring patterns 31 to 33 constituted by first to third solid wirings are formed.

As shown in FIG. 5, a first sealing-side joining pattern 35 serving as a first sealing-side sealing part for joining to the piezoelectric diaphragm 10 is provided on the lower surface 30b of the first sealing member 30 on the piezoelectric diaphragm 10 side. The first sealing-side joining pattern 35 is formed in an annular shape in plan view. The first vibration-side joining pattern 23 on the piezoelectric diaphragm 10 side and the first sealing-side joining pattern 35 of the first sealing member 30 are provided at positions where they overlap each other in plan view.

Six through-hole electrodes (first to sixth through-hole electrodes 33a to 33f) that pass through between the upper surface 30a and the lower surface 30b and have a conductive material formed on the inner wall surface are formed in the first sealing member 30. Specifically, the first to fourth through-hole electrodes 33a to 33d are respectively provided in regions of the four corners (corner portions) of the first sealing member 30. The fifth and sixth through-hole electrodes 33e and 33f are provided on the inner side of the first sealing-side joining pattern 35 of the first sealing member 30 in plan view.

On the lower surface 30b of the first sealing member 30, first to third lower surface-side connection joining patterns 33ab to 33cb that are electrically connected to the first to third through-hole electrodes 33a to 33c are formed on the periphery of the first to third through-hole electrodes 33a to 33c. Note that the first wiring pattern 31 electrically connected to the first through-hole electrode 33a, the third wiring pattern 33 electrically connected to the second and fourth through-hole electrodes 33b and 33d, and the second wiring pattern 32 electrically connected to the third through-hole electrode 33c are on the upper surface 30a of the first sealing member 30. Also, the first sealing-side joining pattern 35 electrically connected to the fourth through-hole electrode 33d is on the lower surface 30b of the first sealing member 30. On the lower surface 30b of the first sealing member 30, a fifth lower surface-side connection joining pattern 33eb that is electrically connected to the fifth through-hole electrode 33e is formed on the periphery of the fifth through-hole electrode 33e. Note that the first wiring pattern 31 electrically connected to the fifth through-hole electrode 33e is on the upper surface 30a of the first sealing member 30. On the lower surface 30b of the first sealing member 30, a sixth lower surface-side connection joining pattern 33fb that is electrically connected to the sixth through-hole electrode 33f is formed on the periphery of the sixth through-hole electrode 33f. Note that the second wiring pattern 32 electrically connected to the sixth through-hole electrode 33f is on the upper surface 30a of the first sealing member 30.

A seventh lower surface-side connection joining pattern 33gb is formed on the lower surface 30b of the first sealing member 30. The seventh lower surface-side connection joining pattern 33bg is electrically connected to the first connection joining pattern 22 on the upper surface 10a of the piezoelectric diaphragm 10. Also, a first wiring pattern 36 that electrically connects the fifth lower surface-side connection joining pattern 33eb to the seventh lower surface-side connection joining pattern 33gb is formed on the lower surface 30b of the first sealing member 30.

Eighth to tenth lower surface-side connection joining patterns 33hb to 33jb that are electrically connected to the first to third lower surface-side connection joining patterns 33ab to 33cb are formed on the lower surface 30b of the first sealing member 30.

Finally, the second sealing member 40 will be described with reference to FIGS. 8 and 9.

The second sealing member 40 is a substantially rectangular parallelepiped substrate formed from a single quartz crystal plate, and the surface on the side joined to the piezoelectric diaphragm 10 is formed as a flat smooth surface (mirror finishing). In the present embodiment, an AT-cut quartz crystal plate is used as the second sealing member 40, as with the piezoelectric diaphragm 10.

A second sealing-side joining pattern 41 serving as a second sealing-side sealing part for joining to the piezoelectric diaphragm 10 is provided on an upper surface 40a of the second sealing member 40 on the piezoelectric diaphragm 10 side. The second sealing-side joining pattern 41 is formed in an annular shape in plan view. The second vibration-side joining pattern 28 on the piezoelectric diaphragm 10 side and the second sealing-side joining pattern 41 of the second sealing member 40 are provided at positions where they overlap each other in plan view.

As shown in FIG. 9, on the lower surface 40b of the second sealing member 40 corresponding to the lower surface of the piezoelectric vibrator 3 (outer bottom surface of piezoelectric vibrator 3), the first to fourth external connection terminals (correspond to “external connection terminals” of the present invention) 45a to 45d are formed in a peripheral portion of the lower surface 40b (peripheral portion of outer bottom surface of piezoelectric vibrator 3). The first external connection terminal 45a is an input terminal, and the third external connection terminal 45c is an output terminal. Also, the second external connection terminal 45b and the fourth external connection terminal 45d are both ground terminals.

The disposition positions of the first to fourth external connection terminals 45a to 45d on the lower surface 40b of the second sealing member 40 will now be described.

In the piezoelectric vibrator 3 including the piezoelectric diaphragm 10, the first sealing member 30, and the second sealing member 40, a first sealing path 6A is formed by the piezoelectric diaphragm 10 and the first sealing member 30 being diffusion bonded in a state where the first vibration-side joining pattern 23 and the first sealing-side joining pattern 35 are overlaid on each other (see FIG. 3). Also, a second sealing path 6B is formed by the piezoelectric diaphragm 10 and the second sealing member 40 being diffusion bonded in a state where the second vibration-side joining pattern 28 and the second sealing-side joining pattern 41 are overlaid on each other (see FIG. 3). The package with a sandwich structure shown in FIG. 3 is thereby manufactured. The first and second sealing paths 6A and 6B are formed in an annular shape in plan view. The internal space C1 in which the vibration part 11 of the piezoelectric diaphragm 10 including the first excitation electrode 20 and the second excitation electrode 25 is airtightly sealed is thereby formed.

In the piezoelectric vibrator 3 in which the first and second sealing paths 6A and 6B are formed by diffusion bonding in this way, there is a gap of 1.00 μm or less between the first sealing member 30 and the piezoelectric diaphragm 10, and a gap of 1.00 μm or less between the second sealing member 40 and the piezoelectric diaphragm 10. In other words, the thickness of the first sealing path 6A between the first sealing member 30 and the piezoelectric diaphragm 10 is 1.00 μm or less (e.g., 0.15 μm to 1.00 μm in Au—Au bond), and the thickness of the second sealing path 6B between the second sealing member 40 and the piezoelectric diaphragm 10 is 1.00 μm or less (e.g., 0.15 μm to 1.00 μm in Au—Au bond).

In FIG. 9, a boundary line L1 between the internal space C1 and an outer frame part W1 is shown with a one-dot chain line. In other words, the boundary line L1 is the outer peripheral edge of the internal space C1 and the inner peripheral edge of the outer frame part W1. In the present embodiment, the boundary line L1 is provided at a position that, in plan view, substantially coincides with the inner peripheral edge of the outer frame part 12 of the piezoelectric diaphragm 10.

The outer frame part W1 is a portion, in the piezoelectric vibrator 3, in which the first sealing member 30 and the piezoelectric diaphragm 10 are located close to each other and the second sealing member 40 and the piezoelectric diaphragm 10 are located close to each other, with substantially no gap therebetween. Being located close to each other with substantially no gap therebetween means that the gap between the first sealing member 30 and the piezoelectric diaphragm 10 and the gap between the second sealing member 40 and the piezoelectric diaphragm 10 is 1.00 μm or less, for example. In the present embodiment, the outer frame part W1 is provided at a position that, in plan view, substantially coincides with the outer frame part 12 of the piezoelectric diaphragm 10.

The internal space C1 is a portion, in the piezoelectric vibrator 3 in which the first sealing member 30 and the piezoelectric diaphragm 10 are not located close to each other and the second sealing member 40 and the piezoelectric diaphragm 10 are not located close to each other, and have a gap therebetween. In this case, the gap between the first sealing member 30 and the piezoelectric diaphragm 10 and the gap between the second sealing member 40 and the piezoelectric diaphragm 10 is larger than 1.00 μm, for example. The space between the vibration part 11 and the outer frame part 12 of the piezoelectric diaphragm 10 is also part of the internal space C1. The internal space C1 is provided on the inner peripheral side relative to the first and second sealing paths 6A and 6B. In the present embodiment, the internal space C1 is provided in a position that substantially coincides with the region on the inner side of the outer frame part 12 of the piezoelectric diaphragm 10 in plan view.

In the first embodiment, the first to fourth external connection terminals 45a to 45d are each disposed along the outer frame part W1 (outer frame part 12 of piezoelectric diaphragm 10) that surrounds the internal space C1 in plan view. In the present embodiment, the first to fourth external connection terminals 45a to 45d are each disposed so as to partially overlap the outer frame part W1 in plan view. Also, the first to fourth external connection terminals 45a to 45d are respectively disposed in the four corners of the lower surface 40b of the second sealing member 40.

The first to fourth external connection terminals 45a to 45d are each disposed to overlap only the outer frame part W1 and not span between the outer frame part W1 and the internal space C1 in plan view, except for a protruding part 45ab of the first external connection terminal 45a.

The center of the lower surface 40b of the second sealing member 40 in plan view will be referred to as center C. The first external connection terminal 45a is formed such that an edge 45aa of the first external connection terminal 45a nearest the center C extends away from the center C in plan view. In the present embodiment, the first external connection terminal 45a bends such that the edge 45aa extends away from the center C in plan view, and, in plan view, has a substantially L shape that extends parallel to the fourth long side 3d and then bends substantially perpendicularly and extends parallel to the first short side 3a. Additionally, the first external connection terminal 45a is provided with the protruding part 45ab that serves as an indicator (index) of the mounting direction of the piezoelectric vibrator 3. Note that the indicator is not limited to the protruding part 45ab, and may be, for example, a chamfer such as a C chamfer (angled surface) or an R chamfer (rounded surface).

The second external connection terminal 45b is formed such that an edge 45ba of the second external connection terminal 45b nearest the center C extends away from the center C in plan view. In the present embodiment, the second external connection terminal 45b bends such that the edge 45ba extends away from the center C in plan view, and, in plan view, has a substantially L shape that extends parallel to the first short side 3a and then bends substantially perpendicularly and extends parallel to the second long side 3b.

The third external connection terminal 45c is formed such that an edge 45ca of the third external connection terminal 45c nearest the center C extends away from the center C in plan view. In the present embodiment, the third external connection terminal 45c bends such that the edge 45ca extends away from the center C in plan view, and, in plan view, has a substantially L shape that extends parallel to the second long side 3b and then bends substantially perpendicularly and extends parallel to the third short side 3c.

The fourth external connection terminal 45d is formed such that an edge 45da of the fourth external connection terminal 45d nearest the center C extends away from the center C in plan view. In the present embodiment, the fourth external connection terminal 45d bends such that the edge 45ca extends away from the center C in plan view, and, in plan view, has a substantially L shape that extends parallel to the third short side 3c and then bends substantially perpendicularly and extends parallel to the fourth long side 3d.

Four through-hole electrodes (first to fourth through-hole electrodes 42a to 42d) that pass through between the upper surface 40a and the lower surface 40b and have a conductive material formed on the inner wall surface are formed in the second sealing member 40. Specifically, the first to fourth through-hole electrodes 42a to 42d are respectively provided in the regions of the four corners (corner portions) of the second sealing member 40.

On the upper surface 40a of the second sealing member 40, first to third upper surface-side connection joining patterns 42aa to 42ca that are electrically connected to the first to third through-hole electrodes 42a to 42c are formed on the periphery of the first to third through-hole electrodes 42a to 42c. Note that the first to third external connection terminals 45a to 45c electrically connected to the first to third through-hole electrodes 42a to 42c are on the lower surface 40b of the second sealing member 40. Also, the second sealing-side joining pattern 41 electrically connected to the fourth through-hole electrode 42d is on the upper surface 40a of the second sealing member 40, and the fourth external connection terminal 45d electrically connected to the fourth through-hole electrode 42d is on the lower surface 40b of the second sealing member 40.

Fifth to seventh upper surface-side connection joining patterns 42ea to 42ga that are electrically connected to the first to third upper surface-side connection joining patterns 42aa to 42ca are formed on the upper surface 40a of the second sealing member 40.

In the piezoelectric vibrator 3, the first external connection terminal 45a is electrically connected to the second excitation electrode 25, via the first through-hole electrode 42a, the first upper surface-side connection joining pattern 42aa, the fifth upper surface-side connection joining pattern 42ea/sixth lower surface-side connection joining pattern 24fb, the first lower surface-side connection joining pattern 24ab, the first through-hole electrode 24a, the first upper surface-side connection joining pattern 24aa, the sixth upper surface-side connection joining pattern 24fa/eighth lower surface-side connection joining pattern 33hb, the first lower surface-side connection joining pattern 33ab, the first through-hole electrode 33a, the first wiring pattern 31, the fifth through-hole electrode 33e, the fifth lower surface-side connection joining pattern 33eb, the first wiring pattern 36, the seventh lower surface-side connection joining pattern 33gb, the fifth upper surface-side connection joining pattern 24ea, the fifth through-hole electrode 24e, the second connection joining pattern 27, and the second lead wiring 26.

Also, in the piezoelectric vibrator 3, the third external connection terminal 45c is electrically connected to the first excitation electrode 20, via the third through-hole electrode 42c, the third upper surface-side connection joining pattern 42ca, the seventh upper surface-side connection joining pattern 42ga/seventh lower surface-side connection joining pattern 24gb, the third lower surface-side connection joining pattern 24cb, the third through-hole electrode 24c, the third upper surface-side connection joining pattern 24ca, the seventh upper surface-side connection joining pattern 24ga/tenth lower surface-side connection joining pattern 33jb, the third lower surface-side connection joining pattern 33cb, the third through-hole electrode 33c, the second wiring pattern 32, the sixth through-hole electrode 33f, the sixth lower surface-side connection joining pattern 33fb, the first connection joining pattern 22, and the first lead wiring 21.

Also, in the piezoelectric vibrator 3, the second external connection terminal 45b is electrically connected to the third wiring pattern 33, via the second through-hole electrode 42b, the second upper surface-side connection joining pattern 42ba, the sixth upper surface-side connection joining pattern 42fa/eighth lower surface-side connection joining pattern 24hb, the second lower surface-side connection joining pattern 24bb, the second through-hole electrode 24b, the first vibration-side joining pattern 23, the ninth lower surface-side connection joining pattern 33ib, the second lower surface-side connection joining pattern 33bb, and the second through-hole electrode 33b.

Also, in the piezoelectric vibrator 3, the fourth external connection terminal 45d is electrically connected to the third wiring pattern 33, via the fourth through-hole electrode 42d, the second sealing-side joining pattern 41, the second vibration-side joining pattern 28, the fourth through-hole electrode 24d, the first vibration-side joining pattern 23, the first sealing-side joining pattern 35, and the fourth through-hole electrode 33d.

The electronic component 4 is an IC (Integrated Circuit) that controls the piezoelectric vibrator 3 and is mounted to the upper surface 2a of the substrate 2 by wire bonding. The electronic component 4 includes an electronic circuit such as an oscillator circuit that generates a predetermined oscillation output, and outputs the oscillation output generated by the oscillator circuit externally as a reference signal such as a clock signal.

As shown in FIG. 1, first to sixth external connection terminals 4a to 4f having a substantially rectangular shape in plan view are formed on the upper surface of the electronic component 4. The first to sixth external connection terminals 4a to 4f are, for example, the following terminals. The first external connection terminal 4a is a clock input terminal and is electrically connected by wire to a first electronic component mounting pad 53a formed on the upper surface 2a of the substrate 2. Also, the second external connection terminal 4b is an output enable terminal and is electrically connected by wire to a second electronic component mounting pad 53b formed on the upper surface 2a of the substrate 2. Also, the third external connection terminal 4c is a power supply terminal and is electrically connected by wire to a third electronic component mounting pad 53c formed on the upper surface 2a of the substrate 2. Also, the fourth external connection terminal 4d is a clock output terminal and is electrically connected by wire to a fourth electronic component mounting pad 53d formed on the upper surface 2a of the substrate 2. Also, the fifth external connection terminal 4e is a ground terminal and is electrically connected by wire to a fifth electronic component mounting pad 53e formed on the upper surface 2a of the substrate 2. Also, the sixth external connection terminal 4f is an oscillator output terminal and is electrically connected by wire to a sixth electronic component mounting pad 53f formed on the upper surface 2a of the substrate 2.

The substrate 2 is an insulating substrate on which the piezoelectric vibrator 3 and the electronic component 4 are electrically connected by a wiring pattern and integrally constituted, and is made of a resin material. As a base material, the substrate 2 uses a glass epoxy resin which is an insulator on which processing such as cutting is readily performed, for example.

As shown in FIGS. 1 and 10, the substrate 2 has a substantially rectangular shape in which a first side 50a and a third side 50c are the long sides, and a second side 50b and a fourth side 50d are the short sides. Note that, hereinafter, the first side 50a and the third side 50c will be referred to as first long side 50a and third long side 50c, and the second side 50b and the fourth side 50d will be referred to as second short side 50b and fourth short side 50d.

The plan view size of the substrate 2 is 2.0 mm×1.6 mm and 3.2 mm×2.5 mm, but is not limited thereto, and may be other sizes in plan view. Note that in “◯◯◯ mm×ΔΔΔ mm”, ◯◯◯ mm is the length of the first long side 50a and the third long side 50b, and ΔΔΔmm is the length of the second short side 50b and the fourth short side 50d.

As shown in FIGS. 1 and 3, the piezoelectric vibrator 3 and the electronic component 4 are mounted to the upper surface (corresponds to “one main surface” of the present invention) 2a of the substrate 2. An overlapping region where the upper surface 2a of the substrate 2 and the piezoelectric vibrator 3 overlap each other in plan view is substantially rectangular. As shown in FIGS. 1, 3 and 10, a recessed part (first to fourth recessed parts 51a to 51d: correspond to “recessed part” of the present invention) is, with respect to each corner of the overlapping region of the upper surface 2a in plan view, formed so as to include the corner and a periphery thereof.

The recessed parts (first to fourth recessed parts 51a to 51d) have a shape that allows the external connection terminals (first to fourth external connection terminals 45a to 45d) of the piezoelectric vibrator 3 to be disposed therein, and are recessed in a direction perpendicular to the upper surface 2a.

The first recessed part 51a has, in plan view, a substantially L shape that extends parallel to the fourth short side 50d and then bends substantially perpendicularly and extends parallel to the first long side 50a. Also, the second recessed part 51b has, in plan view, a substantially L shape that extends parallel to the first long side 50a and then bends substantially perpendicularly and extends parallel to the second short side 50b. Also, the third recessed part 51c has, in plan view, a substantially L shape that extends parallel to the second short side 50b and then bends substantially perpendicularly and extends parallel to the third long side 50c. Also, the fourth recessed part 51d has, in plan view, a substantially L shape that extends parallel to the third long side 50c and then bends substantially perpendicularly and extends parallel to the fourth short side 50d.

As shown in FIG. 10, on the upper surface 2a of the substrate 2, the first piezoelectric vibrator mounting pad 52a is formed on the bottom surface of the first recessed part 51a, the second piezoelectric vibrator mounting pad 52b is formed on the bottom surface of the second recessed part 51b, the third piezoelectric vibrator mounting pad 52c is formed on the bottom surface of the third recessed part 51c, and the fourth piezoelectric vibrator mounting pad 52d is formed on the bottom surface of the fourth recessed part 51d. The first to fourth piezoelectric vibrator mounting pads 52a to 52d are, for example, the following terminals. The first piezoelectric vibrator mounting pad 52a is a terminal connected to the first external connection terminal 45a which is an input terminal of the piezoelectric vibrator 3. The second piezoelectric vibrator mounting pad 52b is a terminal connected to the second external connection terminal 45b which is a ground terminal of the piezoelectric vibrator 3. The third piezoelectric vibrator mounting pad 52c is a terminal connected to the third external connection terminal 45b which is an output terminal of the piezoelectric vibrator 3. The fourth piezoelectric vibrator mounting pad 52c is a terminal connected to the fourth external connection terminal 45d which is a ground terminal of the piezoelectric vibrator 3. Note that the first to fourth piezoelectric vibrator mounting pads 52a to 52d correspond to the “piezoelectric vibrator mounting pads” of the present invention.

The center, in plan view, of the overlapping region on the upper surface 2a of the substrate 2 where the upper surface 2a of the substrate 2 and the piezoelectric vibrator 3 overlap each other will be referred to as center C. The first piezoelectric vibrator mounting pad 52a is formed such that an edge 52aa of the first piezoelectric vibrator mounting pad 52a nearest the center C extends away from the center C in plan view. In the present embodiment, the first piezoelectric vibrator mounting pad 52a bends such that the edge 52aa extends away from the center C in plan view and, in plan view, has a substantially L shape that extends parallel to the fourth short side 50d and then bends substantially perpendicularly and extends parallel to the first long side 50a. In plan view, there is a gap between the opposing lateral faces of the first piezoelectric vibrator mounting pad 52a and the first recessed part 51a. Also, in plan view, the first piezoelectric vibrator mounting pad 52a (mounting surface of first piezoelectric vibrator mounting pad 52a) has an analogous shape (“analogous” includes congruent; this similarly applies to the other piezoelectric vibrator mounting pads) or a similar shape to the first external connection terminal 45a of the piezoelectric vibrator 3 (in the present embodiment, the shape is similar). Also, in plan view, the first piezoelectric vibrator mounting pad 52a (mounting surface of first piezoelectric vibrator mounting pad 52a) is formed at a position where the first external connection terminal 45a is joinable thereto.

The second piezoelectric vibrator mounting pad 52b is formed such that an edge 52ba of the second piezoelectric vibrator mounting pad 52b nearest the center C extends away from the center C in plan view. In the present embodiment, the second piezoelectric vibrator mounting pad 52b bends such that the edge 52ba extends away from the center C and, in plan view, has a substantially L shape that extends parallel to the first long side 50a and then bends substantially perpendicularly and extends parallel to the second short side 50b. In plan view, there is a gap between the opposing lateral faces of the second piezoelectric vibrator mounting pad 52b and the second recessed part 51b. Also, in plan view, the second piezoelectric vibrator mounting pad 52b (mounting surface of second piezoelectric vibrator mounting pad 52b) has an analogous shape or a similar shape to the second external connection terminal 45b of the piezoelectric vibrator 3 (in the present embodiment, the shape is similar). Also, in plan view, the second piezoelectric vibrator mounting pad 52b (mounting surface of second piezoelectric vibrator mounting pad 52b) is formed at a position where the second external connection terminal 45b is joinable thereto.

The third piezoelectric vibrator mounting pad 52c is formed such that an edge 52ca of the third piezoelectric vibrator mounting pad 52c nearest the center C extends away from the center C in plan view. In the present embodiment, the third piezoelectric vibrator mounting pad 52c bends such that the edge 52ca extends away from the center C in plan view, and, in plan view, has a substantially L shape that extends parallel to the second short side 50b and then bends substantially perpendicularly and extends parallel to the third long side 50c. In plan view, there is a gap between the opposing lateral faces of the third piezoelectric vibrator mounting pad 52c and the third recessed part 51c. Also, in plan view, the third piezoelectric vibrator mounting pad 52c (mounting surface of third piezoelectric vibrator mounting pad 52c) has an analogous shape or a similar shape to the third external connection terminal 45c of the piezoelectric vibrator 3 (in the present embodiment, the shape is similar). Also, in plan view, the third piezoelectric vibrator mounting pad 52c (mounting surface of third piezoelectric vibrator mounting pad 52c) is formed at a position where the third external connection terminal 45c is joinable thereto.

The fourth piezoelectric vibrator mounting pad 52d is formed such that an edge 52da of the fourth piezoelectric vibrator mounting pad 52d nearest the center C extends away from the center C in plan view. In the present embodiment, the fourth piezoelectric vibrator mounting pad 52d bends such that the edge 52ca extends away from the center C in plan view, and, in plan view, has a substantially L shape that extends parallel to the third long side 50c and then bends substantially perpendicularly and extends parallel to the fourth short side 50d. In plan view, there is a gap between the opposing lateral faces of the fourth piezoelectric vibrator mounting pad 52d and the fourth recessed part 51d. Also, in plan view, the fourth piezoelectric vibrator mounting pad 52d (mounting surface of fourth piezoelectric vibrator mounting pad 52d) has an analogous shape or a similar shape to the fourth external connection terminal 45d of the piezoelectric vibrator 3 (in the present embodiment, the shape is similar). Also, in plan view, the fourth piezoelectric vibrator mounting pad 52d (mounting surface of fourth piezoelectric vibrator mounting pad 52d) is formed at a position where the fourth external connection terminal 45d is joinable thereto.

The piezoelectric vibrator 3 is mounted to the upper surface 2a of the substrate 2, as a result of the first to fourth external connection terminals 45a to 45d being joined to the mounting surfaces of the first to fourth piezoelectric vibrator mounting pads 52a to 52d using solder (corresponds to “solder” of the present invention) H (see FIG. 3). In this mounting, as described above, the piezoelectric vibrator 3 is mounted to the upper surface 2a of the substrate 2, such that the first short side 3a and third short side 3c of the piezoelectric vibrator 3 are substantially orthogonal to the second short side 50b and fourth short side 50d of the substrate 2 in plan view.

As shown in FIG. 10, on the upper surface 2a of the substrate 2, a substantially rectangular fifth recessed part 51e is formed to include the corner where the first long side 50a and the second short side 50b intersect and its periphery in plan view. Also, on the upper surface 2a of the substrate 2, a substantially rectangular sixth recessed part 51f is formed to include the corner where the first long side 50a and the second short side 50b intersect and its periphery in plan view. The fifth and sixth recessed parts 51e and 51f are recessed in a direction perpendicular to the upper surface 2a.

On the upper surface 2a of the substrate 2, the first to third electronic component mounting pads 53a to 53c that are substantially rectangular in plan view are formed on the bottom surface of the fifth recessed part 51e, and the fourth to sixth electronic component mounting pads 53d to 53f that are substantially rectangular in plan view are formed on the bottom surface of the sixth recessed part 51f. The first to sixth electronic component mounting pads 53a to 53f are, for example, the following terminals. The first electronic component mounting pad 53a is a clock input terminal and is electrically connected by wire to the first external connection terminal 4a of the electronic component 4. Also, the second electronic component mounting pad 53b is an output enable terminal and is electrically connected by wire to the second external connection terminal 4b of the electronic component 4. Also, the third electronic component mounting pad 53c is a power supply terminal and is electrically connected by wire to the third external connection terminal 4c of the electronic component 4. Also, the fourth electronic component mounting pad 53d is a clock output terminal and is electrically connected by wire to the fourth external connection terminal 4d of the electronic component 4. Also, the fifth electronic component mounting pad 53e is a ground terminal and is electrically connected by wire to the fifth external connection terminal 4e of the electronic component 4. Also, the sixth electronic component mounting pad 53f is an oscillator output terminal and is electrically connected by wire to the sixth external connection terminal 4f of the electronic component 4.

As shown in FIG. 10, a first wiring pattern 54a constituted by a first internal wiring pattern that is electrically connected to the first piezoelectric vibrator mounting pad 52a and a first upper surface-side connection joining pattern that is electrically joined to the first internal wiring pattern is formed on the upper surface 2a side of the substrate 2. Also, a second wiring pattern 54b constituted by a second internal wiring pattern that is electrically connected to the third piezoelectric vibrator mounting pad 52c and a second upper surface-side connection joining pattern that is electrically joined to the second internal wiring pattern is formed on the upper surface 2a side of the substrate 2. Also, a third wiring pattern 54c constituted by a third internal wiring pattern that electrically connects the second piezoelectric vibrator mounting pad 52b to the fourth piezoelectric vibrator mounting pad 52d is formed on the upper surface 2a side of the substrate 2. Also, a fourth wiring pattern 54d constituted by a fourth internal wiring pattern that electrically connects the first piezoelectric vibrator mounting pad 52a to the first electronic component mounting pad 53a is formed on the upper surface 2a side of the substrate 2. Also, a fifth wiring pattern 54e constituted by a fifth internal wiring pattern that electrically connects the third piezoelectric vibrator mounting pad 52c to the fourth electronic component mounting pad 53d is formed on the upper surface 2a side of the substrate 2.

Also, a sixth wiring pattern 54f constituted by a sixth internal wiring pattern that electrically connects the second piezoelectric vibrator mounting pad 52b to the fifth electronic component mounting pad 53e and a sixth upper surface-side connection joining pattern that is electrically joined to the sixth internal wiring pattern is formed on the upper surface 2a side of the substrate 2. Also, a seventh wiring pattern 54g constituted by a seventh internal wiring pattern that is electrically connected to the second electronic component mounting pad 53b and a seventh upper surface-side connection joining pattern that is electrically joined to the seventh internal wiring pattern is formed on the upper surface 2a side of the substrate 2. Also, an eighth wiring pattern 54h constituted by an eighth internal wiring pattern that is electrically connected to the third electronic component mounting pad 53c and an eighth upper surface-side connection joining pattern that is electrically joined to the eighth internal wiring pattern is formed on the upper surface 2a side of the substrate 2. Also, a ninth wiring pattern 54i constituted by a ninth internal wiring pattern that is electrically connected to the sixth electronic component mounting pad 53f and a ninth upper surface-side connection joining pattern that is electrically joined to the ninth internal wiring pattern is formed on the upper surface 2a side of the substrate 2.

As shown in FIG. 2, on the lower surface 2b of the substrate 2, a substantially rectangular recessed part (first to fourth recessed parts 55a to 55d) is, with respect to each corner of the lower surface 2b, formed so as to include the corner and a periphery thereof in plan view. The first to fourth recessed parts 55a to 55d are recessed in a direction perpendicular to the lower surface 2b.

On the lower surface 2b of the substrate 2, a first external connection terminal 56a is formed on the bottom surface of the first recessed part 55a, a second external connection terminal 56b is formed on the bottom surface of the second recessed part 55b, a third external connection terminal 56c is formed on the bottom surface of the third recessed part 55c, and a fourth external connection terminal 56d is formed on the bottom surface of the fourth recessed part 55d. The first to fourth external connection terminals 56a to 56d are utilized when mounting the piezoelectric vibration device 1 to another device (substrate, etc.). The first to sixth external connection terminals 56a to 56d are, for example, the following terminals. The first external connection terminal 56a is a power supply terminal. Also, the second external connection terminal 56b is a clock output terminal. Also, the third external connection terminal 56c is a ground terminal. Also, the fourth external connection terminal 56d is an output enable terminal.

The first external connection terminal 56a has a substantially rectangular shape in plan view, and there is a gap between the opposing lateral faces of the first external connection terminal 56a and the first recessed part 55a. Also, the second external connection terminal 56b has a substantially rectangular shape in plan view, and there is a gap between the opposing lateral faces of the second external connection terminal 56b and the second recessed part 55b. Also, the third external connection terminal 56c has a substantially rectangular shape in plan view, and there is a gap between the opposing lateral faces of the third external connection terminal 56c and the third recessed part 55c. Also, the fourth external connection terminal 56d has a substantially rectangular shape in plan view, and there is a gap between the opposing lateral faces of the fourth external connection terminal 56d and the fourth recessed part 55d. Additionally, the fourth external connection terminal 56d is chamfered to form a C chamfer (angled surface) that serves as an indicator of the mounting direction of the piezoelectric vibration device 1. Note that the indicator is not limited to a C chamfer (angled surface), and may, for example, be another chamfered surface such as an R chamfer (rounded surface), or a protrusion or the like.

A first wiring pattern 57a constituted by a first internal wiring pattern that is electrically connected to the first external connection terminal 56a is formed on the lower surface 2b side of the substrate 2, and the first wiring pattern 57a extends to the lateral face of the substrate 2. Also, a second wiring pattern 57b constituted by a second internal wiring pattern that is electrically connected to the first external connection terminal 56a and a second lower surface-side connection joining pattern that is electrically joined to the second internal wiring pattern is formed on the lower surface 2b side of the substrate 2. Also, a third wiring pattern 57c constituted by a third internal wiring pattern that is electrically connected to the second external connection terminal 56b is formed on the lower surface 2b side of the substrate 2, and the third wiring pattern 57c extends to the lateral face of the substrate 2. Also, a fourth wiring pattern 57d constituted by a fourth internal wiring pattern that is electrically connected to the second external connection terminal 56b and a fourth lower surface-side connection joining pattern that is electrically joined to the fourth internal wiring pattern is formed on the lower surface 2b side of the substrate 2. Also, a fifth wiring pattern 57e constituted by a fifth internal wiring pattern that is electrically connected to the third external connection terminal 56c and a fifth lower surface-side connection joining pattern that is electrically joined to the fifth internal wiring pattern is formed on the lower surface 2b side of the substrate 2.

Also, a sixth wiring pattern 57f constituted by a sixth internal wiring pattern that is electrically connected to the third external connection terminal 56c is formed on the lower surface 2b side of the substrate 2, and the sixth wiring pattern 57f extends to the lateral face of the substrate 2. Also, a seventh wiring pattern 57g constituted by a seventh internal wiring pattern that is electrically connected to the fourth external connection terminal 56d and branches with one branch extending to the lateral face of the substrate 2 and a seventh lower surface-side connection joining pattern that is electrically joined to the distal end of the other branch of the seventh internal wiring pattern is formed on the lower surface 2b side of the substrate 2. Also, an eighth wiring pattern 57h constituted by an eighth internal wiring pattern that extends at one end to the lateral face of the substrate 2 and an eighth lower surface-side connection joining pattern that is electrically joined to the eighth internal wiring pattern is formed on the lower surface 2b side of the substrate 2. Also, a ninth wiring pattern 57i constituted by a ninth internal wiring pattern that extends at one end to the lateral face of the substrate 2 and a ninth lower surface-side connection joining pattern that is electrically joined to the ninth internal wiring pattern is formed on the lower surface 2b side of the substrate 2.

Six through-hole electrodes (first to sixth through-hole electrodes 58a to 58f) that have a conductive material formed on the inner wall surface are formed in the substrate 2. The first through-hole electrode 58a electrically connects the first wiring pattern 54a on the upper surface 2a side of the substrate 2 to the eighth wiring pattern 57h on the lower surface 2b side of the substrate 2. The second through-hole electrode 58b electrically connects the second wiring pattern 54b on the upper surface 2a side of the substrate 2 to the ninth wiring pattern 57i on the lower surface 2b side of the substrate 2. The third through-hole electrode 58c electrically connects the eighth wiring pattern 54h on the upper surface 2a side of the substrate 2 to the second wiring pattern 57b on the lower surface 2b side of the substrate 2. The fourth through-hole electrode 58d electrically connects the sixth wiring pattern 54f on the upper surface 2a side of the substrate 2 to the fifth wiring pattern 57e on the lower surface 2b side of the substrate 2. The fifth through-hole electrode 58e electrically connects the ninth wiring pattern 54i on the upper surface 2a side of the substrate 2 to the fourth wiring pattern 57d on the lower surface 2b side of the substrate 2. The sixth through-hole electrode 58f electrically connects the seventh wiring pattern 54g on the upper surface 2a side of the substrate 2 to the seventh wiring pattern 57g on the lower surface 2b side of the substrate 2.

The first external connection terminal 56a is electrically connected to the third electronic component mounting pad 53c, via the second wiring pattern 57b, the third through-hole electrode 58c, and the eighth wiring pattern 54h. The second external connection terminal 56b is electrically connected to the sixth electronic component mounting pad 53f, via the fourth wiring pattern 57d, the fifth through-hole electrode 58e, and the ninth wiring pattern 54i. The third external connection terminal 56c is electrically connected to the second piezoelectric vibrator mounting pad 52b and the fifth electronic component mounting pad 53e, via the fifth wiring pattern 57e, the fourth through-hole electrode 58d, and the sixth wiring pattern 54f. The fourth external connection terminal 56d is electrically connected to the second electronic component mounting pad 53b, via the seventh wiring pattern 57g, the sixth through-hole electrode 58f, and the seventh wiring pattern 54g. The eighth wiring pattern 57h is electrically connected to the first piezoelectric vibrator mounting pad 52a, via the first through-hole electrode 58a and the first wiring pattern 54a. The ninth wiring pattern 57i is electrically connected to the third piezoelectric vibrator mounting pad 52c, via the second through-hole electrode 58b and the second wiring pattern 54b.

The sealing resin 5 is a thermosetting resin such as an epoxy resin, and, as shown in FIG. 3, is molded on the upper surface 2a side of the substrate 2 so as to cover the piezoelectric vibrator 3 and the electronic component 4. In plan view, the periphery of the substrate 2 substantially coincide with the periphery of the sealing resin 5.

Here, the positional relationship between the piezoelectric vibrator 3 and the sealing resin 5 in plan view will be described with reference to FIG. 11. Note that, in FIG. 11, only the piezoelectric vibrator 3 and the sealing resin 5 are illustrated, and illustration of the substrate 2, the electronic component 4, and the like is omitted.

As shown in FIG. 11, the sealing resin 5 has, in plan view, a substantially rectangular shape in which a first side 5a and a third side 5c opposing each other are the long sides, and a second side 5b and a fourth side 5d opposing each other are the short sides. Note that, hereinafter, the first side 5a and the third side 5c will be referred to as first long side 5a and third long side 5c, and the second side 5b and the fourth side 5d will be referred to as second short side 5b and fourth short side 5d. Here, the piezoelectric vibration device 1 is formed through dicing as a result of the sealing resin 5 being cut together with the substrate 2 after being molded, and thus the peripheral edge of the substrate 2 coincides with the peripheral edge of the sealing resin 5 in plan view, and the external dimensions of the substrate 2 are the same as the sealing resin 5.

In plan view, the sides (first long side 5a, second short side 5b, third long side 5c, fourth short side 5d) constituting the outer lateral faces of the sealing resin 5 and the sides (first short side 3a, second long side 3b, third short side 3c, fourth long side 3d) constituting the lateral faces of the piezoelectric vibrator 3 respectively oppose each other. Note that the sides of the sealing resin 5 (first long side 5a, second short side 5b, third long side 5c, fourth short side 5d) are respectively parallel to the sides of the piezoelectric vibrator 3 (first short side 3a, second long side 3b, third short side 3c, fourth long side 3d). Here, as described above, the external dimensions of the sealing resin 5 and the substrate 2 are the same, and thus the first long side 5a, the second short side 5b, the third long side 5c, and the fourth short side 5d of the sealing resin 5 in plan view respectively correspond to the first long side 50a, the second short side 50b, the third long side 50c, and the fourth short side 50d of the substrate 2 described above in plan view.

The lengths of the first long side 5a and third long side 5c and the second short side 5b and fourth short side 5d of the sealing resin 5 in plan view are respectively given as L51 and L52. Also, the lengths of the first short side 3a and third short side 3c and the second long side 3b and fourth long side 3d of the piezoelectric vibrator 3 in plan view are respectively given as L31 and L32. Also, the distance in plan view between the first long side 5a of the sealing resin 5 and the first short side 3a of the piezoelectric vibrator 3 that oppose each other is given as La, the distance in plan view between the second short side 5b of the sealing resin 5 and the second long side 3b of the piezoelectric vibrator 3 that oppose each other is given as Lb, the distance in plan view between the third long side 5c of the sealing resin 5 and the third short side 3c of the piezoelectric vibrator 3 that oppose each other is given as Lc, and the distance in plan view between the fourth short side 5d of the sealing resin 5 and the fourth long side 3d of the piezoelectric vibrator 3 that oppose each other is given as Ld.

When there is one shortest distance among the distances La to Ld, the shortest distance d is set to 7.8% or more, and preferably 10% or more, and 39% or less (D×0.1≤d≤D×0.39) of the dimension of the sealing resin 5 in plan view in the length direction of the shortest distance d (i.e., distance D between side of sealing resin 5 related to shortest distance d and opposing side of sealing resin 5). Note that if the shortest distance d is 7.8% or more, and preferably 10% or more, of the dimension (distance D) of the sealing resin 5 in plan view in the length direction of the shortest distance d, leakage of molten flux or molten solder from the piezoelectric vibration device 1 during reflow can be effectively suppressed. In view of this, in the first embodiment, the lower limit of the ratio of distance d to distance D expressed as a percentage (d/D×100) is set to 10% which is 7.8% or more. Also, when the ratio of distance d to distance D expressed as a percentage (d/D×100) is increased, the plan view size of the substrate 2 increases even if the components, wiring and the like disposed on the upper surface 2a of the substrate 2 are comparable. The external connection terminals of the lower surface 2b of the substrate 2 are usually disposed in the four corners of the substrate 2 which is rectangular in plan view. Thus, when the plan view size of the substrate 2 becomes too large, wiring connected from components disposed on the upper surface 2a of the substrate 2 to the external connection terminals increases in length, possibly resulting in an increase in stray capacitance in the substrate 2 or stray capacitance between the substrate 2 and an external substrate to which the piezoelectric vibration device 1 is mounted. An increase in stray capacitance leads to a change in oscillation frequency. In view of this, the upper limit of the ratio of distance d to distance D expressed as a percentage (d/D×100) is set to 39%.

For example, in FIG. 11, assuming that the distance Ld is the shortest distance among the distances La to Ld, the shortest distance Ld is set to 10% or more and 39% or less (L51×0.1≤Ld≤L51×0.39) of the dimension in plan view of the sealing resin 5 in the length direction of the shortest distance Ld (i.e., distance L51 between fourth short side 5d of sealing resin 5 related to shortest distance Ld and second short side 5b of sealing resin 5 opposing fourth short side 5d). When the plan view size of the substrate 2 is 2.00 mm×1.6 mm, in the first embodiment, the plan view size of the sealing resin 5 is also 2.00 mm×1.6 mm, and thus the distance Ld is set to 10% or more and 39% or less of the distance L51 (=2.00 mm), that is, to 0.2 mm or more and 0.78 mm or less.

Note that the case where there are two shortest distances among the distances La to Ld is as follows. When the distance of one of the shortest distances is given as Lα1, and the dimension of the sealing resin 5 in plan view in the length direction of the distance Lα1 (i.e., distance between side of sealing resin 5 related to one distance Lα1 of shortest distances and opposing side of sealing resin 5) is given as Lβ1, a value obtained by dividing the distance Lα1 by the distance Lβ1 is Lα1/Lβ1. Also, when the distance of the other shortest distance is given as Lα2, and the dimension of the sealing resin 5 in plan view in the length direction of the distance La2 (i.e., distance between side of sealing resin 5 related to other distance Lα2 of shortest distances and opposing side of sealing resin 5) is given as Lβ2, the value obtained by dividing the distance Lα2 by the distance Lβ2 is Lα2/Lβ2. When the value Lα1/Lβ1 is less than or equal to the value Lα2/Lβ2 , the size related to the value Lα1/Lβ1 is utilized, and the distance Lα1 is set to 10% or more and 39% or less of the distance Lβ1(Lβ1×0.1≤Lα≤Lβ1×0.39). Note that, in the case where the value Lα2/Lβ2 is less than or equal to the value Lα1/Lβ1, the size related to the value Lα2/Lβ2 is utilized.

For example, in FIG. 11, assume that the two distances Lc and Ld are the shortest distances among the distances La to Ld. The value obtained by dividing the one shortest distance Ld by the dimension of the sealing resin 5 in plan view in the length direction of the one distance Ld (i.e., distance L51 between fourth short side 5d of sealing resin 5 related to one shortest distance Ld and second short side 5b of sealing resin 5 opposing fourth short side 5d) is Ld/L51. The value obtained by dividing the other shortest distance Lc by the dimension of the sealing resin 5 in plan view in the length direction of the other distance Lc (i.e., distance L52 between third long side 5c of sealing resin 5 related to other shortest distance Lc and first long side 5a of sealing resin 5 opposing third long side 5c) is Lc/L52. When the value Ld/L51 is compared with the value Lc/L52, Ld=Lc and L51>L52 (L51 is long side, L52 is short side), and thus Ld/L51<Lc/L52. Therefore, the distance Ld is set to 10% or more and 39% or less of the distance L51 (L51×0.1≤Ld≤L51×0.39).

Note that, in the case where there are three or more shortest distances among the distances La to Ld, the shortest distances are set, based on the same idea as in the case where there are two shortest distances among the distances La to Ld.

Here, a specific example of the dimensions of the piezoelectric vibration device 1 will be described. Here, cases where the plan view size of the substrate 2 is (1) 2.0 mm×1.6 mm and (2) 3.2 mm×2.5 mm will be described. In the present embodiment, the periphery of the substrate 2 substantially coincides with the periphery of the sealing resin 5 in plan view, and thus the plan view size of the sealing resin 5 is 2.0 mm×1.6 mm in the case of (1), and 3.2 mm ×2.5 mm in the case of (2).

(1) Case where the size is 2.0 Mm×1.6 Mm

The piezoelectric vibrator 3 having a size of 0.85 mm×1.05 mm in plan view is disposed on the upper surface 2a of the substrate 2 having a size of 2.0 mm×1.6 mm in plan view such that the distances Ld and Lc among the distances La to Ld are the shortest distances. The plan view size of the sealing resin 5 is 2.0 mm×1.6 mm. L51=2.0 mm, L52=1.6 mm, L31=0.85 mm, and L32=1.05 mm.

When Lc/L52 is compared with Ld/L51, Lc=Ld and L51>L52, and thus Ld/L51<Lc/L52. The smaller value Ld/L51 is set to 0.1 or more and 0.39 or less (Ld/L51×100 is set to 10% or more and 39% or less), and, in this example, Ld/L51=0.1 (Ld/L51×100=10%). The distance Ld is Ld=L51×0.1=2.0>0.1=0.2 mm. In this case, the distances La, Lb, and Lc are La=0.35 mm, Lb=0.95 mm, and Lc=0.2 mm.

In summary,
L51=2.0 mm,
L52=1.6 mm,
L31=0.85 mm,
L32=1.05 mm,
La=0.35 mm,
Lb=0.95 mm,
Lc=0.2 mm, and
Ld=0.2 mm.
   (2) Case where the size is 3.2 mm×2.5 mm

The piezoelectric vibrator 3 having a size of 0.85 mm×1.05 mm in plan view is disposed on the upper surface 2a of the substrate 2 having a size of 3.2 mm×2.5 mm in plan view, such that the distances Ld and Lc among the distances La to Ld are the shortest distances. The plan view size of the sealing resin 5 is 3.2 mm×2.5 mm. L51=3.2 mm, L52=2.5 mm, L31=0.85 mm, and L32=1.05 mm.

When Lc/L52 is compared with Ld/L51, Lc=Ld and L51>L52, and thus Ld/L51<Lc/L52. The smaller value Ld/L51 is set to 0.1 or more and 0.39 or less (Ld/L51×100 is set to 10% or more and 39% or less), and, in this example, Ld/L51=0.25 (Ld/L51×100=25%). The distance Ld is Ld=L51×0.25=3.2×0.25=0.8 mm. In this case, the distances La, Lb, and Lc are La=0.65 mm, Lb=1.55 mm, and Lc=0.8 mm.

In summary,
L51=3.2 mm
L52=2.5 mm,
L31=0.85 mm,
L32=1.05 mm,
La=0.65 mm,
Lb=1.55 mm,
Lc=0.8 mm, and
Ld=0.8 mm.

Note that the plan view size of the piezoelectric vibrator 3 in the above specific examples is given as an example, and the plan view size is not limited thereto. For example, the plan view size may be another plan view size such as 1.6 mm×1.0 mm.

As described above, in relation to the first to fourth external connection terminals 45a to 45d formed on the outer bottom surface of the piezoelectric vibrator 3 (lower surface 40b of second sealing member 40) and the first to fourth piezoelectric vibrator mounting pads 52a to 52d formed on the upper surface 2a of the substrate 2, the piezoelectric vibrator mounting pads each have, in plan view, an analogous shape or a similar shape to the external connection terminal to be joined thereto (in the present embodiment, the shape is similar). Hereinafter, the case where the shape is similar will be described.
(1) As shown in FIG. 12(a), the lengths of the sides of the external connection terminal 45A are given as LA1 to LA4, and the lengths of the sides of the piezoelectric vibrator mounting pad 52A are given as LB1 to LB4. In the case where the external connection terminal 45A is L-shaped in plan view, and the piezoelectric vibrator mounting pad 52A is L-shaped in plan view, the relationship whereby the piezoelectric vibrator mounting pad 52A has a similar shape to the external connection terminal 45A is satisfied, even if the ratios of the sides are not equal (e.g., (LA1/LA2)/(LB1/LB2)≠1, (LA4/LA2)/(LB4/LB2)≠1, (LA3/LA1)/(LB3/LB1)≠1, etc.).
(2) The relationship whereby the piezoelectric vibrator mounting pad 52B has a similar shape to the external connection terminal 45B is also satisfied in the case where the external connection terminal 45B is chamfered with a C chamfer (angled surface) but the piezoelectric vibrator mounting pad 52B is not chamfered, as shown in FIG. 12(b). Note that the similar shape relationship is also satisfied in the case where the chamfer is an R chamfer (rounded surface) or the like. The similar shape relationship is also satisfied in the case where the external connection terminal is not chamfered but the piezoelectric vibrator mounting pad is chamfered. The similar shape relationship is also satisfied in the case where both the external connection terminal and the piezoelectric vibrator mounting pad are chamfered but the position of the corner that is chamfered differs or the size of the chamfer differs.
(3) The relationship whereby the piezoelectric vibrator mounting pad has a similar shape to the external connection terminal is also satisfied in the case where a protrusion is formed on the external connection terminal but a protrusion is not formed on the piezoelectric vibrator mounting pad (see first external connection terminal 45a in FIG. 9 and first piezoelectric vibrator mounting pad 52a in FIG. 10). Note that the similar shape relationship is also satisfied in the case where a protrusion is not formed on the external connection terminal but a protrusion is formed on the piezoelectric vibrator mounting pad. The similar shape relationship is also satisfied in the case where a protrusion is formed on both the external connection terminal and the piezoelectric vibrator mounting pad but the position at which the protrusion is formed differs or the dimensions of the protrusion differ. The similar shape relationship is also satisfied in the case of a recess rather than a protrusion.
(4) The relationship whereby the piezoelectric vibrator mounting pad 52C has a similar shape to the external connection terminal 45C is also satisfied in the case where the bend angle of an edge 45C1 of the external connection terminal 45C differs from the bend angle of an edge 52C1 of the piezoelectric vibrator mounting pad 52C, as shown in FIG. 12(c).
(5) The relationship whereby the piezoelectric vibrator mounting pad 52D has a similar shape to the external connection terminal 45D is also satisfied in the case where an edge 45D1 of the external connection terminal 45C bends and an edge 52D1 of the piezoelectric vibrator mounting pad 52D curves slightly, as shown in FIG. 12(d).
(6) The relationship whereby the piezoelectric vibrator mounting pad has a similar shape to the external connection terminal is also satisfied in the case where the above (1) to (5) are combined as appropriate.
(7) The relationship whereby the piezoelectric vibrator mounting pad has a similar shape to the external connection terminal is also satisfied in the case where the piezoelectric vibrator mounting pad and a figure obtained by enlarging or reducing the external connection terminal satisfy any of the relationships of (1) to (6) above, in addition the case where the piezoelectric vibrator mounting pad and a figure the same as the external connection terminal satisfy any of the relationships of (1) to (6) above.

Note that the above examples (1) to (7) are merely given as examples of similar shapes, and it is not intended that the similar shapes be limited to the above examples (1) to (7).

According to the first embodiment described above, in plan view, the shortest distance (Ld) among the distances (La to Ld) between the opposing sides of the outer lateral faces of the sealing resin 5 and the lateral faces of the piezoelectric vibrator 3 is 10% or more of the dimension of the sealing resin 5 in the length direction of the shortest distance Ld (i.e., distance L51 between fourth short side 5d of sealing resin 5 related to shortest distance Ld and second short side 5b of sealing resin 5 opposing fourth short side 5d), and thus a distance effective in suppressing leakage of flux or solder from the sealing resin during reflow can be provided between the fourth short side 5d of the sealing resin 5 and the fourth long side 3d of the piezoelectric vibrator 3 where the distance is shortest. Leakage of molten flux or molten solder from the piezoelectric vibration device 1 during reflow can thereby be suppressed.

Also, although the substrate 2 having a rectangular shape in plan view is more likely to warp on the long sides than on the short sides, warping of the substrate 2 can be suppressed, by mounting the piezoelectric vibrator 3 to the substrate 2 such that the short sides of the piezoelectric vibrator 3 are orthogonal to the short sides of the substrate. Thus, during reflow, movement of molten flux or molten solder flowing in the direction of the outer lateral faces of the sealing resin 5 can be suppressed, and leakage of molten flux or molten solder from the piezoelectric vibration device 1 can be further suppressed.

Also, the first to fourth piezoelectric vibrator mounting pads 52a to 52d are each formed to be substantially L-shaped in plan view, and bend such that the edges of the first to fourth piezoelectric vibrator mounting pads 52a to 52d nearest the center (center of overlapping region where piezoelectric vibrator 3 and substrate 2 overlap in plan view) c extend away from the center C in plan view. The portion where molten flux and molten solder accumulate on the inner side surrounded by the first to fourth piezoelectric vibrator mounting pads 52a to 52d can thus be enlarged in plan view, compared with the case where the four piezoelectric vibrator mounting pads each have a substantially rectangular shape. Leakage of molten flux and molten solder from the piezoelectric vibration device 1 can thereby be further suppressed.

Also, molten flux and molten solder can be pooled in the gap between the lateral faces of the first to fourth piezoelectric vibrator mounting pads 52a to 52d and the lateral faces of the first to fourth recessed parts 51a to 51d during reflow, thus enabling leakage of molten flux and molten solder from the piezoelectric vibration device 1 to be suppressed.

Also, the first to fourth piezoelectric vibrator mounting pads 52a to 52d formed on the upper surface 2a of the substrate 2 each have an analogous shape or a similar shape to the corresponding external connection terminal among the first to fourth external connection terminals 45a to 45d formed on the outer bottom surface of the piezoelectric vibrator 3 (lower surface 40b of second sealing member 40), when the upper surface 2a of the substrate 2 is viewed from the vertical direction. In other words, each of the first to fourth piezoelectric vibrator mounting pads 52a to 52d is formed to be substantially L-shaped, such that the edge thereof nearest the center of the overlapping region where the piezoelectric vibrator 3 overlaps the substrate 2 extends away from the center in plan view. The region surrounded by the edges of the first to fourth piezoelectric vibrator mounting pads 52a to 52d nearest the center Can thereby be enlarged. A large number of elements such as wiring and through-hole electrodes can thereby be disposed in that region, and the piezoelectric vibration device 1 can be reduced in size. Furthermore, misalignment of the mounting of the piezoelectric vibrator 3 to the first to fourth piezoelectric vibrator mounting pads 52a to 52d can be prevented, as a result of the first to fourth piezoelectric vibrator mounting pads 52a to 52d all having an analogous shape or a similar shape to the corresponding external connection terminal among the first to fourth external connection terminals 45a to 45d.

Also, the distance between the first to fourth external connection terminals 45a to 45d can be increased, as a result of the piezoelectric vibrator 3 having a substantially rectangular shape in plan view, and the first to fourth external connection terminals 45a to 45d being respectively disposed in the four corners of the outer bottom surface of the piezoelectric vibrator 3 (lower surface 40b of second sealing member 40). For example, when joining the first to fourth external connection terminals 45a to 45d of the piezoelectric vibrator 3 to the first to fourth piezoelectric vibrator mounting pads 52a to 52d formed on the upper surface 2a of the substrate 2 using solder, short-circuiting between the first to the fourth external connection terminals 45a to 45d during the joining can thereby be prevented.

Also, the first to fourth external connection terminals 45a to 45d are each substantially L-shaped in plan view, such that the edges of the first to fourth external connection terminals 45a to 45d on the center C (center of outer bottom surface of piezoelectric vibrator 3) side of the lower surface 40b of the second sealing member 40 extend away from the center C. Jutting out of the first to fourth external connection terminals 45a to 45d in the direction of the center C of the lower surface 40b of the second sealing member 40 with the reduction in size of the piezoelectric vibration device 1 can thereby be suppressed. For example, when joining the first to fourth external connection terminals 45a to 45d of the piezoelectric vibrator 3 to the first to fourth piezoelectric vibrator mounting pads 52a to 52d formed on the upper surface 2a of the substrate 2 using solder, short-circuiting between the first to the fourth external connection terminals 45a to 45d during the joining can thereby be prevented.

Also, the first to fourth external connection terminals 45a to 45d are disposed in the region of the outer frame part W1 in plan view, and thus the portions of the first to fourth external connection terminals 45a to 45d overlapping the internal space can be reduced as much as possible. When mounting the piezoelectric vibrator 3 to the substrate 2, stress acting on the first and second sealing paths (sealing parts) 6A and 6B due to deformation of the second sealing member 40 can thereby be reduced, and misalignment of the mounting of the piezoelectric vibrator 3 on the first to fourth piezoelectric vibrator mounting pads 52a to 52d formed on the upper surface of the substrate 2 can be suppressed.

### Second Embodying Mode

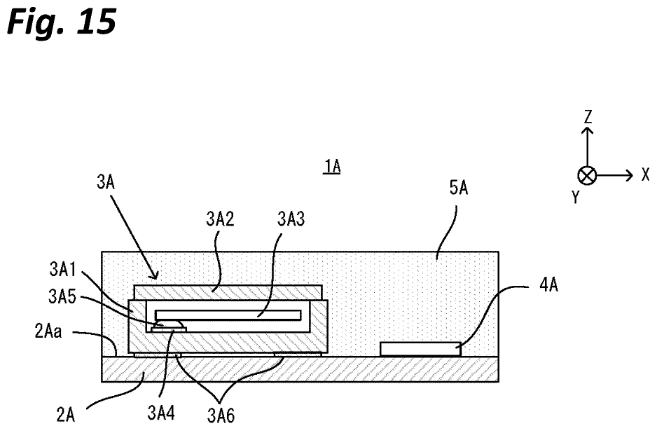

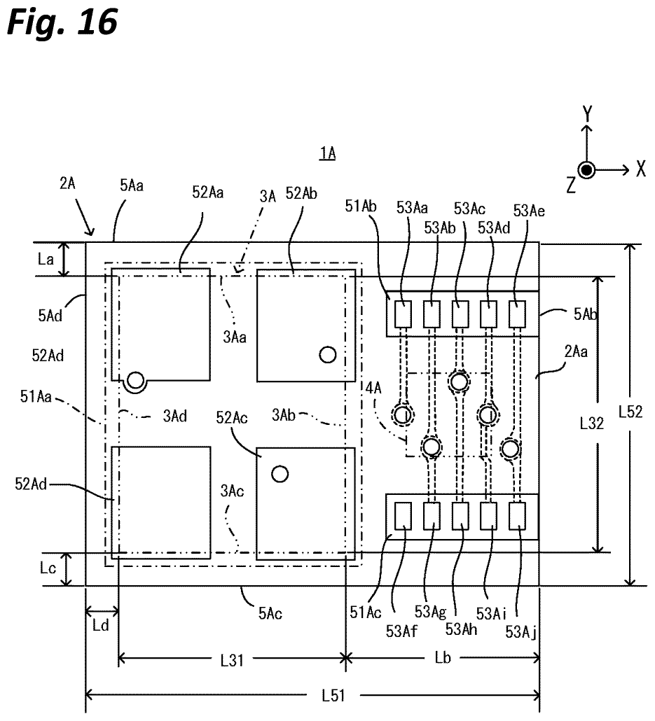

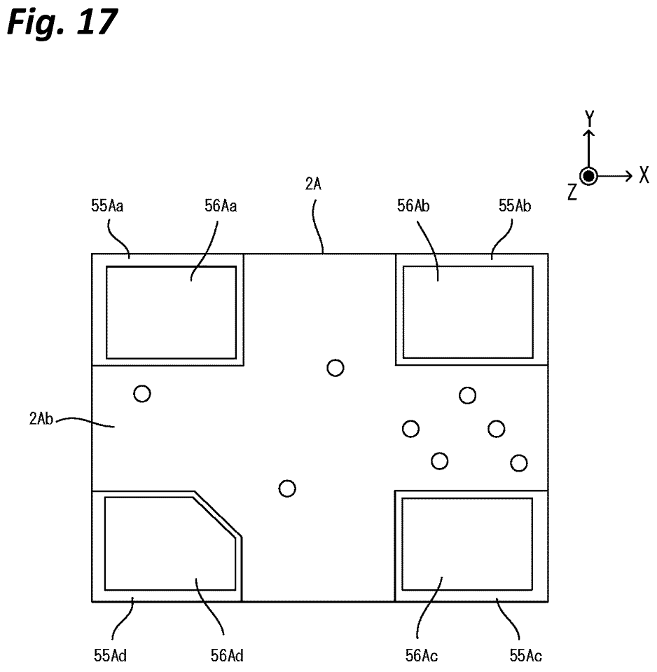

A piezoelectric vibration device according to a second embodiment of the present invention will be described with reference to FIGS. 15 to 17. FIG. 15 is a schematic cross-sectional view (sectional front view) of the piezoelectric vibration device according to the second embodiment of the present invention. FIG. 16 is a schematic plan view of the upper surface side of the piezoelectric vibration device excluding the sealing resin according to the second embodiment. FIG. 17 is a schematic plan view of a state in which the substrate is rendered visible from the upper surface side of the piezoelectric vibration device in FIG. 16.

In the first embodiment, the case where the multilayer piezoelectric vibrator 3 including the piezoelectric diaphragm 10, the first sealing member 30, and the second sealing member 40 is solder-mounted as a piezoelectric vibrator is described, whereas the second embodiment differs from the first embodiment in that a surface-mounted piezoelectric vibrator that does not have a multilayer structure is solder-mounted, with the following description focusing on the differences from the first embodiment. Note that, in FIGS. 15 to 17, reference numerals that are the same as in FIGS. 1 to 11 indicate elements that are the same or equivalent.

As shown in the schematic diagram (cross-sectional view) of FIG. 15, a piezoelectric vibration device 1A according to the second embodiment includes a surface-mounted piezoelectric vibrator 3A and an electronic component 4A that are mounted to an upper surface 2Aa of a substrate 2A, and a sealing resin 5A molded on the upper surface 2Aa side of the substrate 2A so as to cover the piezoelectric vibrator 3A and the electronic component 4A. Similarly to the first embodiment, the peripheral edge of the substrate 2A coincides with the peripheral edge of the sealing resin 5A in plan view, and, hereinafter, the long sides and short sides of the substrate 2A will be respectively described as long sides and short sides of the sealing resin 5A, with a first side 5Aa and a third side 5Ac of the sealing resin 5A being referred to as first long side 5Aa and third long side 5Ac, and a second side 5Ab and a fourth side 5Ad being referred to as second short side 5Ab and fourth short side 5Ad. Note that, as shown in FIG. 15, this piezoelectric vibrator 3A includes a box-shaped ceramic package 3A1 having an upper opening portion, a lid 3A2 that is joined to the opening portion of the package 3A1 and closes the opening portion, a piezoelectric vibration piece 3A3 that has excitation electrodes (not shown) formed on the front and back (upper and lower) main surfaces thereof and is housed in the package 3A1, a piezoelectric vibrator mounting pad 3A4 disposed on the inner bottom surface of the package 3A1, a conductive adhesive 3A5 that is laminated on the piezoelectric vibrator mounting pad 3A4 and conductively joins the piezoelectric vibration piece 3A3 to the piezoelectric vibrator mounting pad 3A4, and an external connection terminal 3A6 that is provided in the four corners of the lower surface of the bottom portion of the package 3A1, with the piezoelectric vibrator 3A having a structure in which the box-shaped ceramic package 3A1 is airtightly sealed.

Also, as shown in FIG. 16, in plan view, the sides (first long side 5Aa, second short side 5Ab, third long side 5Ac, fourth short side 5Ad) constituting the lateral faces of the sealing resin 5A and the sides (first short side 3Aa, second long side 3Ab, third short side 3Ac, fourth long side 3Ad) constituting the lateral faces of the piezoelectric vibrator 3A respectively oppose each other. Note that the sides (first long side 5Aa, second short side 5Ab, third long side 5Ac, fourth short side 5Ad) of the sealing resin 5A are respectively parallel to the sides (first short side 3Aa, second long side 3Ab, third short side 3Ac, fourth long side 3Ad) of the piezoelectric vibrator 3A.

As shown in FIG. 16, a rectangular parallelepiped recessed part (rectangle shown with one-dot chain line representing inner wall surface of sealing resin 5A in FIG. 16) 51Aa in which the surface-mounted piezoelectric vibrator 3A is arranged is provided in the upper surface 2Aa of the substrate 2A, and the piezoelectric vibrator 3A whose rectangular outer shape is shown with a two-dot chain line in the diagram is arranged in this recessed part 51Aa. The external connection terminal 3A6 is formed as described above in each of the four corners of the lower surface of the surface-mounted piezoelectric vibrator 3A, piezoelectric vibrator mounting pads 52Aa, 52Ab, 52Ac, and 52Ad for connecting these external connection terminals 3A6 are formed in the four corners of the recessed part 51Aa, and the external connection terminals 3A6 on the lower surface of the piezoelectric vibrator 3A are respectively joined to the piezoelectric vibrator mounting pads 52Aa, 52Ab, 52Ac, and 52Ad via solder.

Also, as shown in FIG. 16, horizontally long recessed parts 51Ab and 51Ac that are substantially rectangular in plan view are formed in the upper surface 2Aa of the substrate 2A. Electronic component mounting pads 53Aa, 53Ab, 53Ac, 53Ad, and 53Ae that are substantially rectangular in plan view are formed on the bottom surface of the recessed part 51Ab, and electronic component mounting pads 53Af, 53Ag, 53Ah, 53Ai, and 53Aj that are substantially rectangular in plan view are formed on the bottom surface of the recessed part 51Ac in the upper surface 2Aa of the substrate 2A. The electronic component 4A (rectangle shown by two-dot chain line in FIG. 16) is disposed between the two recessed parts 51Ab and 51Ac, and external connection terminals of the electronic component 4A are connected to the electronic component mounting pads 53Aa to 53Aj via wiring patterns indicated by the dashed lines in FIG. 16. Note that the circles in FIG. 16 represent vias.

As shown in FIG. 17, cutaway parts 55Aa, 55Ab, 55Ac, and 55Ad that are cutaway in a recessed manner are formed in the four corners of the lower surface 2Ab of the substrate 2A, and external connection terminals 56Aa, 56Ab, 56Ac, and 56Ad are respectively formed in the cutaway parts 55Aa, 55Ab, 55Ac, and 55Ad. These external connection terminals 56Aa to 56Ad are utilized when mounting the piezoelectric vibration device 1A to another device (substrate, etc.). Note that the circles in FIG. 17 correspond to the vias shown by the circles in FIG. 16, and the external connection terminals 56Aa to 56Ad are connected by wiring patterns not shown in FIG. 17.

Similarly to the first embodiment, the lengths of the first long side 5Aa and third long side 5Ac and the second short side 5Ab and fourth short side 5Ad of the sealing resin 5A in plan view are respectively given as L51 and L52, and the lengths of the first short side 3Aa and third short side 3Ac and the second long side 3 Ab and fourth long side 3Ad of the piezoelectric vibrator 3A in plan view are respectively given as L31 and L32. Also, the distance in plan view between the first long side 5Aa of the sealing resin 5A and the opposing first short side 3Aa of the piezoelectric vibrator 3A is given as La, the distance in plan view between the second short side 5Ab of the sealing resin 5A and the opposing second long side 3Ab of the piezoelectric vibrator 3A is given as Lb, the distance in plan view between the third long side 5Ac of the sealing resin 5A and the opposing third short side 3Ac of the piezoelectric vibrator 3A is given as Lc, and the distance in plan view between the fourth short side 5Ad of the sealing resin 5A and the opposing fourth long side 3Ad of the piezoelectric vibrator 3A is given as Ld.

In the second embodiment, similarly to the first embodiment, when there is one shortest distance among the distances La to Ld, the shortest distance d is set to 7.8% or more and 39% or less (D×0.078≤d≤D×0.39) of the dimension of the sealing resin 5A in plan view in the length direction of the shortest distance d (i.e., distance D between side of sealing resin 5A related to shortest distance d and opposing side of sealing resin 5A). Note that if the shortest distance d is 7.8% or more of the dimension (distance D) of the sealing resin 5A in plan view in the length direction of the shortest distance d, leakage of molten flux and molten solder from the piezoelectric vibration device 1A during reflow can be effectively suppressed. In view of this, in the second embodiment, the lower limit of the ratio of distance d to distance D expressed as a percentage (d/D×100) is set to 7.8%. Note that, when the ratio of distance d to distance D expressed as a percentage (d/D×100) is increased, the plan view size of the substrate 2A increases even if the components and wiring disposed on the upper surface 2Aa of the substrate 2A are comparable. The external connection terminals of the lower surface 2Ab of the substrate 2A are usually disposed in the four corners of the substrate 2A having a rectangular shape in plan view. Thus, when the plan view size of the substrate 2A becomes too large, wiring connected from components disposed on the upper surface 2Aa of the substrate 2A to the external connection terminal increases in length, possibly resulting in an increase in stray capacitance in the substrate 2A or stray capacitance between the substrate 2A and an external substrate to which the piezoelectric vibration device 1A is mounted. An increase in stray capacitance leads to a change in oscillation frequency. In view of this, similarly to the first embodiment, the upper limit of the ratio of distance d to distance D expressed as a percentage (d/D×100) is set to 39%.

The substrate 2A in the second embodiment has a rectangular shape whose plan view size is 3.2 mm×2.5 mm, that is, as shown in FIG. 16, whose length L51 of the first and third long sides 5Aa and 5Ac and length L52 of the second and fourth short sides 5Ab and 5Ad of the sealing resin 5A are respectively 3.2 mm and 2.5 mm. When the distance Ld is the shortest distance among the distances La to Ld, the shortest distance Ld is set to 7.8% or more and 39% or less (L51×0.078≤Ld≤L51×0.39) of the dimension of the sealing resin 5A in plan view in the length direction of the shortest distance Ld (i.e., distance L51 between fourth short side 5Ad of sealing resin 5A related to shortest distance Ld and second short side 5Ab of sealing resin 5A opposing fourth short side 5Ad). The plan view size of the substrate 2A is 3.2 mm×2.5 mm, and thus, in the second embodiment, the plan view size of the sealing resin 5A is also 3.2 mm×2.5 mm, and the distance Ld is set to 7.8% or more and 39% or less of the distance L51 (=3.2 mm), that is, to 0.25 mm, which is 0.2496 mm or more and 1.248 mm or less. Note that, in the second embodiment, distance Lb>La=Lc=Ld is set.

In summary,
L51=3.2 mm,
L52=2.5 mm,
La=0.25 mm,
Lc=0.25 mm, and
Ld=0.25 mm.

According to the second embodiment described above, effects comparable to the first embodiment can be obtained. Specifically, the shortest distance (Ld), in plan view, among the distances (La to Ld) between the opposing sides of the outer lateral faces of the sealing resin 5A and the lateral faces of the piezoelectric vibrator 3A is set to 7.8% or more of the dimension of the sealing resin 5A in the length direction of the shortest distance Ld (i.e., distance L51 between fourth short side 5Ad of sealing resin 5A related to shortest distance Ld and second short side 5Ab of sealing resin 5A opposing fourth short side 5Ad), and thus a distance effective in suppressing leakage of flux or solder from the sealing resin during reflow can be provided between the fourth short side 5Ad of the sealing resin 5A and the fourth long side 3Ad of the piezoelectric vibrator 3A where the distance is shortest. Leakage of molten flux or molten solder from the piezoelectric vibration device 1A during reflow can thereby be suppressed.

### Third Embodying Mode

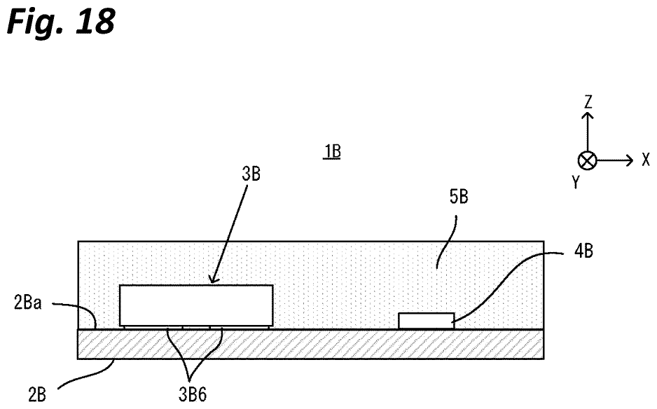

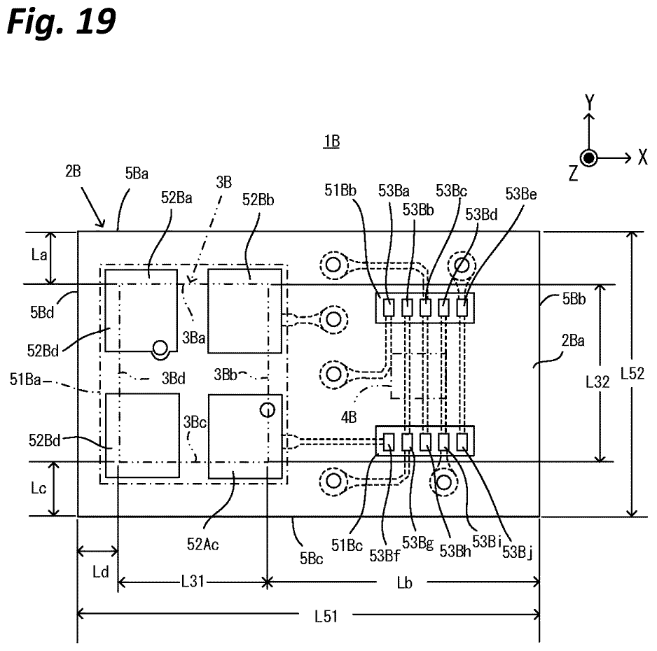

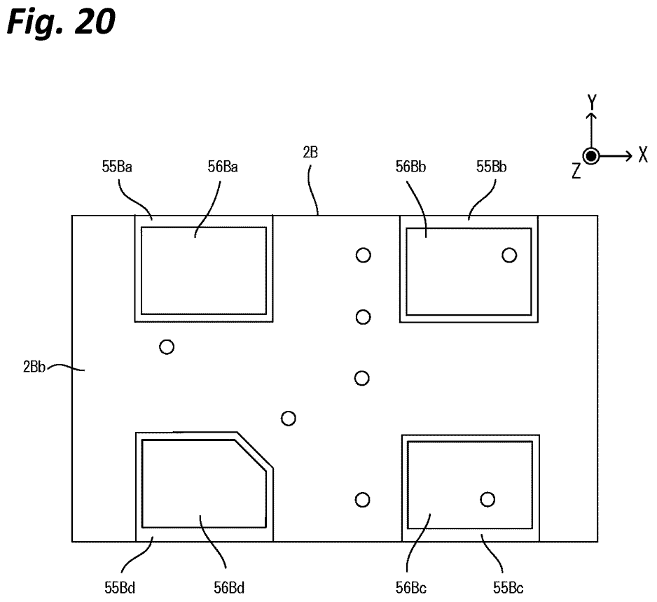

A piezoelectric vibration device according to a third embodiment of the present invention will be described with reference to FIGS. 18 to 20. FIG. 18 is a schematic cross-sectional view (sectional front view) of the piezoelectric vibration device according to the third embodiment of the present invention. FIG. 19 is a schematic plan view of the upper surface side of the piezoelectric vibration device excluding the sealing resin according to the third embodiment. FIG. 20 is a schematic plan view in which the substrate is rendered visible from the upper surface side of the piezoelectric vibration device in FIG. 19.

In the third embodiment, a surface-mounted piezoelectric vibrator that does not have a multilayer structure is solder-mounted similarly to the second embodiment, and the substrate size differs from the second embodiment, with the following description focusing on the differences from the first and second embodiments. Note that, in FIGS. 18 to 20, reference numerals that are the same as in FIGS. 1 to 11 and FIGS. 15 to 17 indicate elements that are the same or equivalent.

As shown in the schematic diagram (cross-sectional view) of FIG. 18, a piezoelectric vibration device 1B according to the third embodiment includes a surface-mounted piezoelectric vibrator 3B and an electronic component 4B that are mounted to an upper surface 2Ba of a substrate 2B, and a sealing resin 5B molded on the upper surface 2Ba side of the substrate 2B so as to cover the piezoelectric vibrator 3B and the electronic component 4B, similarly to the second embodiment. The peripheral edge of the substrate 2B coincides with the peripheral edge of the sealing resin 5B in plan view, and, hereinafter, the long sides and short sides of the substrate 2B will be respectively described as long sides and short sides of the sealing resin 5B, with a first side 5Ba and a third side 5Bc of the sealing resin 5B being referred to as first long side 5Ba and third long side 5Bc, and a second side 5Bb and a fourth side 5Bd being referred to as second short side 5Bb and fourth short side 5Bd. Note that the surface-mounted piezoelectric vibrator 3B has a similar configuration to the piezoelectric vibrator 3A (see FIG. 15) of the second embodiment.

Also, as shown in FIG. 19, in plan view, the sides (first long side 5Ba, second short side 5Bb, third long side 5Bc, fourth short side 5Bd) constituting the lateral faces of the sealing resin 5B and the sides (first short side 3Ba, second long side 3Bb, third short side 3Bc, fourth long side 3Bd) constituting the lateral faces of the piezoelectric vibrator 3B respectively oppose each other. Note that the sides (first long side 5Ba, second short side 5Bb, third long side 5Bc, fourth short side 5Bd) of the sealing resin 5B are respectively parallel to the sides (first short side 3Ba, second long side 3Bb, third short side 3Bc, fourth long side 3Bd) of the piezoelectric vibrator 3B.

As shown in FIG. 19, a rectangular parallelepiped recessed part (rectangle shown with one-dot chain line representing inner wall surface of sealing resin 5B in FIG. 19) 51Ba in which the surface-mounted piezoelectric vibrator 3B is arranged is provided in the upper surface 2Ba of the substrate 2B, and the piezoelectric vibrator 3B whose rectangular outer shape is shown with a two-dot chain line in the diagram is arranged in this recessed part 51Ba. An external connection terminal 3B6 is formed in each of the four corners of the lower surface of the surface-mounted piezoelectric vibrator 3B, piezoelectric vibrator mounting pads 52Ba, 52Bb, 52Bc, and 52Bd for connecting these external connection terminals 3B6 are formed in the four corners of the recessed part 51Ba, and the external connection terminals 3B6 on the lower surface of the piezoelectric vibrator 3B are respectively joined to the piezoelectric vibrator mounting pads 52Ba, 52Bb, 52Bc, and 52Bd via solder.

Also, as shown in FIG. 19, horizontally long recessed parts 51Bb and 51Bc that are substantially rectangular in plan view are formed in the upper surface 2Ba of the substrate 2B. Electronic component mounting pads 53Ba, 53Bb, 53Bc, 53Bd, and 53Be that are substantially rectangular in plan view are formed on the bottom surface of the recessed part 51Bb, and electronic component mounting pads 53Bf, 53Bg, 53Bh, 53Bi, and 53Bj that are substantially rectangular in plan view are formed on the bottom surface of the recessed part 51Bc in the upper surface 2Ba of the substrate 2B. The electronic component 4B (rectangle shown by two-dot chain line in FIG. 19) is disposed between the two recessed parts 51Bb and 51Bc, and external connection terminals of the electronic component 4B are connected to the electronic component mounting pads 53Ba to 53Bj via wiring patterns indicated by the dashed lines in FIG. 19. Note that the circles in FIG. 19 represent vias.

As shown in FIG. 20, cutaway parts 55Ba, 55Bb, 55Bc, and 55Bd that are cutaway in a recessed manner are formed in the four corners of the lower surface 2Bb of the substrate 2B, and external connection terminals 56Ba, 56Bb, 56Bc, and 56Bd are respectively formed in the cutaway parts 55Ba, 55Bb, 55Bc, and 55Bd. These external connection terminals 56Ba to 56Bd are utilized when mounting the piezoelectric vibration device 1B to another device (substrate, etc.). Note that the circles in FIG. 20 correspond to the vias shown by the circles in FIG. 19, and the external connection terminals 56Ba to 56Bd are connected by wiring patterns not shown in FIG. 20.

Similarly to the first and second embodiments, the lengths of the first long side 5Ba and third long side 5Bc and the second short side 5Bb and fourth short side 5Bd of the sealing resin 5B in plan view are respectively given as L51 and L52, and the lengths of the first short side 3Ba and third short side 3Bc and the second long side 3Bb and fourth long side 3Bd of the piezoelectric vibrator 3B in plan view are respectively given as L31 and L32. Also, the distance in plan view between the first long side 5Ba of the sealing resin 5B and the opposing first short side 3Ba of the piezoelectric vibrator 3B is given as La, the distance in plan view between the second short side 5Bb of the sealing resin 5B and the opposing second long side 3Bb of the piezoelectric vibrator 3B is given as Lb, the distance in plan view between the third long side 5Bc of the sealing resin 5B and the opposing third short side 3Bc of the piezoelectric vibrator 3B is given as Lc, and the distance in plan view between the fourth short side 5Bd of the sealing resin 5B and the opposing fourth long side 3Bd of the piezoelectric vibrator 3B is given as Ld.

The substrate 2B in the third embodiment has a rectangular shape whose plan view size is 5.0 mm×3.2 mm, that is, as shown in FIG. 19, whose length L51 of the first and third long sides 5Ba and 5Bc and length L52 of the second and fourth short sides 5Bb and 5Bd of the sealing resin 5B are respectively 5.0 mm and 3.2 mm. When the distance Ld is the shortest distance among the distances La to Ld, the shortest distance Ld is set to 9.0% or more, which is 7.8% or more, and 39% or less (L51×0.09 A≤Ld≤L51×0.39) of the dimension of the sealing resin 5B in plan view in the length direction of the shortest distance Ld (i.e., distance L51 between fourth short side 5Bd of sealing resin 5B related to shortest distance Ld and second short side 5Bb of sealing resin 5B opposing fourth short side 5Bd). The plan view size of the substrate 2B is 5.0 mm×3.2 mm, and thus, in the third embodiment, the plan view size of the sealing resin 5B is also 5.0 mm×3.2 mm, and the distance Ld is set to 9.0% or more and 39% or less of the distance L51 (=5.0 mm), that is, to 0.45 mm or more and 1.95 mm or less. Note that, in the third embodiment, distance Lb>La=Lc>Ld is set.

In summary,
L51=5.0 mm,
L52=3.2 mm, and
Ld=0.45 mm.

According to the third embodiment described above, effects comparable to the first embodiment can be obtained. Specifically, in plan view, the shortest distance (Ld) among the distances (La to Ld) between the opposing sides of the outer lateral faces of the sealing resin 5B and the lateral faces of the piezoelectric vibrator 3B is set to 9.0% (>7.8%) or more of the dimension of the sealing resin 5B in the length direction of the shortest distance Ld (i.e., distance L51 between fourth short side 5Bd of sealing resin 5B related to shortest distance Ld and second short side 5Bb of sealing resin 5B opposing fourth short side 5Bd), and thus a distance effective in suppressing leakage of flux or solder from the sealing resin during reflow can be provided between the fourth short side 5Bd of the sealing resin 5B and the fourth long side 3Bd of the piezoelectric vibrator 3B where the distance is shortest. Leakage of molten flux or molten solder from the piezoelectric vibration device 1B during reflow can thereby be suppressed.

### Fourth Embodying Mode

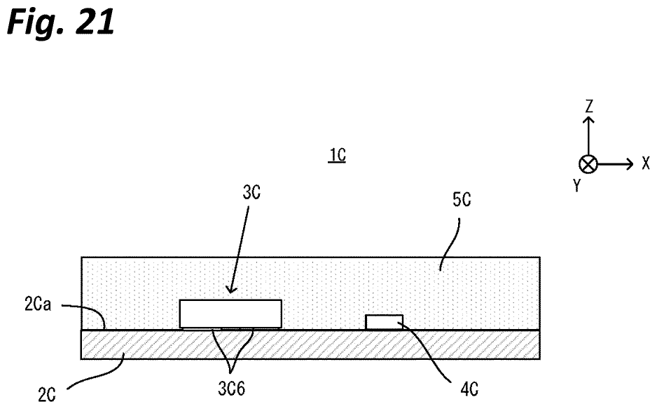

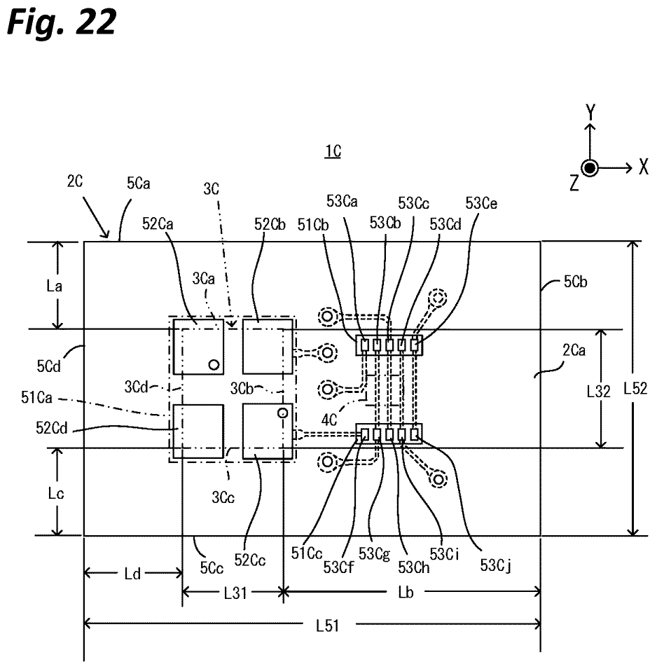

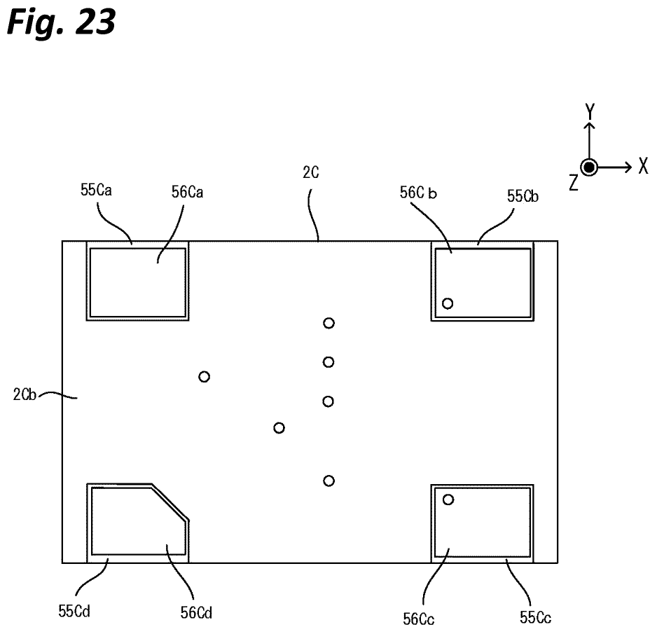

A piezoelectric vibration device according to a fourth embodiment of the present invention will be described with reference to FIGS. 21 to 23. FIG. 21 is a schematic cross-sectional view (sectional front view) of the piezoelectric vibration device according to the fourth embodiment of the present invention. FIG. 22 is a schematic plan view of the upper surface side of the piezoelectric vibration device excluding the sealing resin according to the fourth embodiment. FIG. 23 is a schematic plan view in which the substrate is rendered visible from the upper surface side of the piezoelectric vibration device in FIG. 22.

In the fourth embodiment, a surface-mounted piezoelectric vibrator that does not have a multilayer structure is solder-mounted similarly to the second embodiment, and the substrate size differs from the second embodiment, with the following description focusing on the differences from the first and second embodiments. Note that, in FIGS. 21 to 23, reference numerals that are the same as in FIGS. 1 to 11 and FIGS. 15 to 17 indicate elements that are the same or equivalent.

As shown in the schematic diagram (cross-sectional view) of FIG. 21, a piezoelectric vibration device 1C according to the fourth embodiment includes a surface-mounted piezoelectric vibrator 3C and an electronic component 4C that are mounted to an upper surface 2Ca of a substrate 2C, and a sealing resin 5C molded on the upper surface 2Ca side of the substrate 2C so as to cover the piezoelectric vibrator 3C and the electronic component 4C, similarly to the second embodiment. The peripheral edge of the substrate 2C coincides with the peripheral edge of the sealing resin 5C in plan view, and, hereinafter, the long sides and short sides of the substrate 2C will be respectively described as long sides and short sides of the sealing resin 5C, with a first side 5Ca and a third side 5Cc of the sealing resin 5C being referred to as first long side 5Ca and third long side 5Cc, and a second side 5Cb and a fourth side 5Cd being referred to as second short side 5Cb and fourth short side 5Cd. Note that the surface-mounted piezoelectric vibrator 3C has a similar configuration to the piezoelectric vibrator 3A (see FIG. 15) of the second embodiment.

Also, as shown in FIG. 22, in plan view, the sides (first long side 5Ca, second short side 5Cb, third long side 5Cc, fourth short side 5Cd) constituting the lateral faces of the sealing resin 5C and the sides (first short side 3Ca, second long side 3Cb, third short side 3Cc, fourth long side 3Cd) constituting the lateral faces of the piezoelectric vibrator 3C respectively oppose each other. Note that the sides (first long side 5Ca, second short side 5Cb, third long side 5Cc, fourth short side 5Cd) of the sealing resin 5C are respectively parallel to the sides (first short side 3Ca, second long side 3Cb, third short side 3Cc, fourth long side 3Cd) of the piezoelectric vibrator 3C.

As shown in FIG. 22, a recessed part constituted by a rectangular parallelepiped space (rectangle shown with one-dot chain line representing inner wall surface of sealing resin 5C in FIG. 22) 51Ca in which the surface-mounted piezoelectric vibrator 3C is arranged is provided in the upper surface 2Ca of the substrate 2C, and the piezoelectric vibrator 3C whose rectangular outer shape is shown with a two-dot chain line in the diagram is arranged in this recessed part 51Ca. An external connection terminal 3C6 is formed in each of the four corners of the lower surface of the surface-mounted piezoelectric vibrator 3C, piezoelectric vibrator mounting pads 52Ca, 52Cb, 52Cc, and 52Cd for connecting these external connection terminals 3C6 are formed in the four corners of the recessed part 51Ca, and the external connection terminals 3C6 on the lower surface of the piezoelectric vibrator 3C are respectively joined to the piezoelectric vibrator mounting pads 52Ca, 52Cb, 52Cc, and 52Cd via solder.

Also, as shown in FIG. 22, horizontally long recessed parts 51Cb and 51Cc that are substantially rectangular in plan view are formed in the upper surface 2Ca of the substrate 2C. Electronic component mounting pads 53Ca, 53Cb, 53Cc, 53Cd, and 53Ce that are substantially rectangular in plan view are formed on the bottom surface of the recessed part 51Cb, and electronic component mounting pads 53Cf, 53Cg, 53Ch, 53Ci, and 53Cj that are substantially rectangular in plan view are formed on the bottom surface of the recessed part 51Cc in the upper surface 2Ca of the substrate 2C. The electronic component 4C (rectangle shown by two-dot chain line in FIG. 22) is disposed between the two recessed parts 51Cb and 51Cc, and external connection terminals of the electronic component 4C are connected to the electronic component mounting pads 53Ca to 53Cj via wiring patterns indicated by the dashed lines in FIG. 22. Note that the circles in FIG. 22 represent vias.

As shown in FIG. 23, cutaway parts 55Ca, 55Cb, 55Cc, and 55Cd that are cutaway in a recessed manner are formed in the four corners of the lower surface 2Cb of the substrate 2C, and external connection terminals 56Ca, 56Cb, 56Cc, and 56Cd are respectively formed in the cutaway parts 55Ca, 55Cb, 55Cc, and 55Cd. These external connection terminals 56Ca to 56Cd are utilized when mounting the piezoelectric vibration device 1C to another device (substrate, etc.). Note that the circles in FIG. 23 correspond to the vias shown by the circles in FIG. 22, and the external connection terminals 56Ca to 56Cd are connected by wiring patterns not shown in FIG. 23.

Similarly to the first and second embodiments, the lengths of the first long side 5Ca and third long side 5Cc and the second short side 5Cb and fourth short side 5Cd of the sealing resin 5C in plan view are respectively given as g L51 and L52, and the lengths of the first short side 3Ca and third short side 3Cc and the second long side 3Cb and fourth long side 3Cd of the piezoelectric vibrator 3C in plan view are respectively given as L31 and L32. Also, the distance in plan view between the first long side 5Ca of the sealing resin 5C and the opposing first short side 3Ca of the piezoelectric vibrator 3C is given as La, the distance in plan view between the second short side 5Cb of the sealing resin 5C and the opposing second long side 3Cb of the piezoelectric vibrator 3C is given as Lb, the distance in plan view between the third long side 5Cc of the sealing resin 5C and the opposing third short side 3Cc of the piezoelectric vibrator 3C is given as Lc, and the distance in plan view between the fourth short side 5Cd of the sealing resin 5C and the opposing fourth long side 3Cd of the piezoelectric vibrator 3C is given as Ld.

The substrate 2C in the fourth embodiment has a rectangular shape whose plan view size is 7.3 mm ×5.0 mm, that is, as shown in FIG. 22, whose length L51 of the first and third long sides 5Ca and 5Cc and length L52 of the second and fourth short sides 5Cb and 5Cd of the sealing resin 5C are respectively 7.3 mm and 5.0 mm. When the distance Ld is the shortest distance among the distances La to Ld, the shortest distance Ld is set to 21.9% or more, which is 7.8% or more, and 39% or less (L51×0.219 ≤Ld≤L51×0.39) of the dimension of the sealing resin 5C in plan view in the length direction of the shortest distance Ld (i.e., distance L51 between fourth short side 5Cd of sealing resin 5C related to shortest distance Ld and second short side 5Cb of sealing resin 5C opposing fourth short side 5Cd). The plan view size of the substrate 2C is 7.3 mm ×5.0 mm, and thus, in the fourth embodiment, the plan view size of the sealing resin 5C is also 7.3 mm ×5.0 mm, and the distance Ld is set to 21.9% or more and 39% or less of the distance L51 (=7.3 mm), that is, to 1.6 mm or more and 2.85 mm or less. Note that, in the fourth embodiment, distance Lb>La=Lc>Ld is set.

In summary,
L51=7.3 mm,
L52=5.0 mm, and
Ld=1.6 mm.

According to the fourth embodiment described above, effects comparable to the first embodiment can be obtained. Specifically, in plan view, the shortest distance (Ld) among the distances (La to Ld) between the opposing sides of the outer lateral faces of the sealing resin 5C and the lateral faces of the piezoelectric vibrator 3C is set to 21.9% (>7.8%) or more of the dimension of the sealing resin 5C in the length direction of the shortest distance Ld (i.e., distance L51 between fourth short side 5Cd of sealing resin 5C related to shortest distance Ld and second short side 5Cb of sealing resin 5C opposing fourth short side 5Cd), and thus a distance effective in suppressing leakage of flux or solder from the sealing resin during reflow can be provided between the fourth short side 5Cd of the sealing resin 5C and the fourth long side 3Cd of the piezoelectric vibrator 3C where the distance is shortest. Leakage of molten flux or molten solder from the piezoelectric vibration device 1C during reflow can thereby be suppressed.

### Fifth Embodying Mode

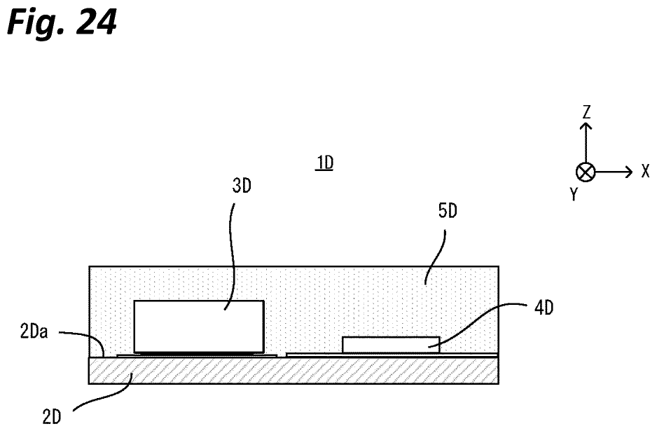

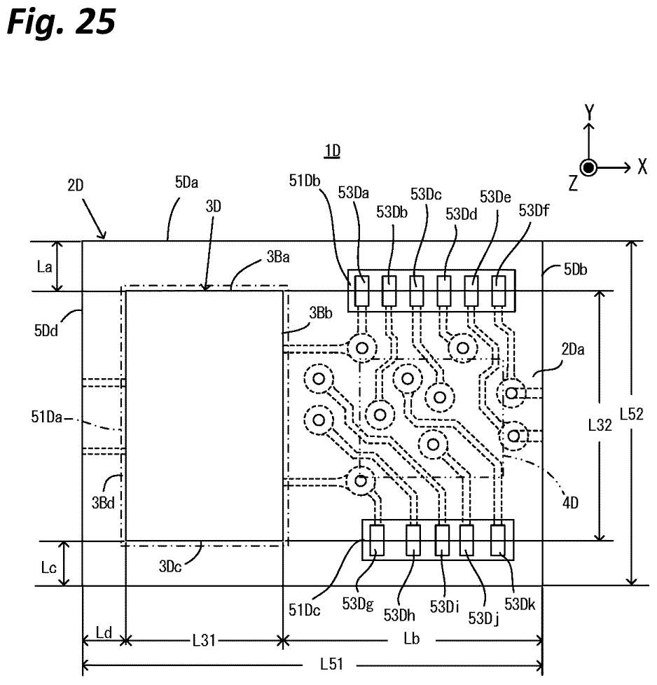

A piezoelectric vibration device according to a fifth embodiment of the present invention will be described with reference to FIGS. 24 and 25. FIG. 24 is a schematic cross-sectional view (sectional front view) of the piezoelectric vibration device according to the fifth embodiment of the present invention. FIG. 25 is a schematic plan view of the upper surface side of the piezoelectric vibration device excluding the sealing resin according to the fifth embodiment.

In the fifth embodiment, the piezoelectric vibration device is constituted by using conductive bumps such as metal bumps to conductively join a surface-mounted piezoelectric vibrator that does not have a multilayer structure unlike the first embodiment and to which a tuning fork vibrator is mounted, and differs from the first embodiment in substrate size, with the following description focusing on the differences from the first embodiment. Note that, in FIGS. 24 and 25, reference numerals that are the same as in FIGS. 1 to 11 indicate elements that are the same or equivalent.

As shown in the schematic diagram (cross-sectional view) of FIG. 24, a piezoelectric vibration device 1D according to the fifth embodiment includes a surface-mounted piezoelectric vibrator 3D and an electronic component 4D that are mounted to an upper surface 2Da of a substrate 2D, and a sealing resin 5D molded on the upper surface 2Da side of the substrate 2D so as to cover the piezoelectric vibrator 3D and the electronic component 4D, similarly to the first embodiment. The peripheral edge of the substrate 2D coincides with the peripheral edge of the sealing resin 5D in plan view, and, hereinafter, the long sides and short sides of the substrate 2D will be respectively described as long sides and short sides of the sealing resin 5D, with a first side 5Da and a third side 5Dc of the sealing resin 5D being referred to as first long side 5Da and third long side 5Dc, and a second side 5Db and a fourth side 5Dd being referred to as second short side 5Db and fourth short side 5Dd. Note that the surface-mounted piezoelectric vibrator 3D has a similar configuration to the piezoelectric vibrator 3A (see FIG. 15) of the second embodiment.

Also, as shown in FIG. 25, in plan view, the sides (first long side 5Da, second short side 5Db, third long side 5Dc, fourth short side 5Dd) constituting the lateral faces of the sealing resin 5D and the sides (first short side 3Da, second long side 3Db, third short side 3Dc, fourth long side 3Dd) constituting the lateral faces of the piezoelectric vibrator 3D respectively oppose each other. Note that the sides (first long side 5Da, second short side 5Db, third long side 5Dc, fourth short side 5Dd) of the sealing resin 5D are respectively parallel to the sides (first short side 3Da, second long side 3Db, third short side 3Dc, fourth long side 3Dd) of the piezoelectric vibrator 3D.

As shown in FIG. 25, a recessed part constituted by a rectangular parallelepiped space (rectangle shown with one-dot chain line representing inner wall surface of sealing resin 5D in FIG. 25) 51Da in which the surface-mounted piezoelectric vibrator 3D is arranged is provided in the upper surface 2Da of the substrate 2D, and the piezoelectric vibrator 3D whose rectangular outer shape is shown with a two-dot chain line in the diagram is arranged in this recessed part 51Da. A plurality of external connection terminals for surface mounting are formed on the lower surface of the surface-mounted piezoelectric vibrator 3D, a plurality of piezoelectric vibrator mounting pads (not shown in FIG. 25) for connecting these external connection terminals are formed in the recessed part 51Da, and the external connection terminals on the lower surface of the piezoelectric vibrator 3D are respectively joined to the piezoelectric vibrator mounting pads via solder.

Also, as shown in FIG. 25, horizontally long recessed parts 51Db and 51Dc that are substantially rectangular in plan view are formed in the upper surface 2Da of the substrate 2D. Electronic component mounting pads 53Da, 53Db, 53Dc, 53Dd, and 53De that are substantially rectangular in plan view are formed on the bottom surface of the recessed part 51Db, and electronic component mounting pads 53Dg, 53Dh, 53Di, 53Dj, and 53Dk that are substantially rectangular in plan view are formed on the bottom surface of the recessed part 51Dc in the upper surface 2Da of the substrate 2D. The electronic component 4D (rectangle shown by two-dot chain line in FIG. 25) is disposed between the two recessed parts 51Db and 51Dc, and external connection terminals of the electronic component 4D are connected to the electronic component mounting pads 53Da to 53Dk via wiring patterns indicated by the dashed lines in FIG. 25. Note that the circles in FIG. 25 represent vias.

Similarly to the first embodiment, the lengths of the first long side 5Da and third long side 5Dc and the second short side 5Db and fourth short side 5Dd of the sealing resin 5D in plan view are respectively given as L51 and L52, and the lengths of the first short side 3Da and third short side 3Dc and the second long side 3Db and fourth long side 3Dd of the piezoelectric vibrator 3D in plan view are respectively given as L31 and L32. Also, the distance in plan view between the first long side 5Da of the sealing resin 5D and the opposing first short side 3Da of the piezoelectric vibrator 3D is given as La, the distance in plan view between the second short side 5 Db of the sealing resin 5D and the opposing second long side 3Db of the piezoelectric vibrator 3D is given as Lb, the distance in plan view between the third long side 5Dc of the sealing resin 5D and the opposing third short side 3Dc of the piezoelectric vibrator 3D is given as Lc, and the distance in plan view between the fourth short side 5Dd of the sealing resin 5D and the opposing fourth long side 3Dd of the piezoelectric vibrator 3D is given as Ld.

The substrate 2D in the fifth embodiment has a rectangular shape whose plan view size is 3.2 mm×2.5 mm, that is, as shown in FIG. 25, whose length L51 of the first and third long sides 5Da and 5Dc and length L52 of the second and fourth short sides 5Db and 5Dd of the sealing resin 5D are respectively 3.2 mm and 2.5 mm. When the distance Ld is the shortest distance among the distances La to Ld, the shortest distance Ld is set to 10.9% or more, which is 7.8% or more, and 39% or less (L51×0.109≤Ld≤L51×0.39) of the dimension of the sealing resin 5D in plan view in the length direction of the shortest distance Ld (i.e., distance L51 between fourth short side 5Dd of sealing resin 5D related to shortest distance Ld and second short side 5Db of sealing resin 5D opposing fourth short side 5Dd). The plan view size of the substrate 2D is 3.2 mm×2.5 mm, and thus, in the fifth embodiment, the plan view size of the sealing resin 5D is also 3.2 mm×2.5 mm, and the distance Ld is set to 10.9% or more and 39% or less of the distance L51 (=3.2 mm), that is, to 0.35 mm or more and 1.248 mm or less. Note that, in the fifth embodiment, distance Lb>La=Lc>Ld is set.

In summary,
L51=3.2 mm,
L52=2.5 mm, and
Ld=0.35 mm.

According to the fifth embodiment described above, effects comparable to the first embodiment can be obtained. Specifically, in plan view, the shortest distance (Ld) among the distances (La to Ld) between the opposing sides of the outer lateral faces of the sealing resin 5D and the lateral faces of the piezoelectric vibrator 3D is set to 10.9% (>7.8%) or more of the dimension of the sealing resin 5D in the length direction of the shortest distance Ld (i.e., distance L51 between fourth short side 5Dd of sealing resin 5D related to shortest distance Ld and second short side 5 Db of sealing resin 5D opposing fourth short side 5Dd), and thus a distance effective in suppressing leakage of flux or solder from the sealing resin during reflow can be provided between the fourth short side 5Dd of the sealing resin 5D and the fourth long side 3Dd of the piezoelectric vibrator 3D where the distance is shortest. Leakage of molten flux or molten solder from the piezoelectric vibration device 1D during reflow can thereby be suppressed.

Note that according to the first to fifth embodiments, leakage of molten flux or molten solder from the piezoelectric vibration devices 1, 1A, 1B, 1C, and 1D during reflow can be suppressed, by setting the shortest distance (Ld) among the distances (La to Ld) between the respective opposing sides of the outer lateral faces of the sealing resins 5, 5A, 5B, 5C, and 5D and the lateral faces of the piezoelectric vibrator 3, 3A, 3B, 3C, and 3D to 7.8% or more of L 51, which is the dimension of the sealing resins 5, 5A, 5B, 5C, and 5D in the length direction of the distance Ld, but, in addition to setting the ratio of distance Ld to distance L51 of the sealing resin to a predetermined value or more, it is desirable to set the wall width of the sealing resins 5, 5A, 5B, 5C, and 5D defining the shortest distance Ld to at least 0.2 mm or more. It thereby becomes possible to provide a distance effective in suppressing leakage of flux or solder from the sealing resin during reflow, enabling leakage of molten flux or molten solder from the piezoelectric vibration devices 1, 1A, 1B, 1C, and 1D during reflow to be suppressed.

Additionally, various design changes can be made to the aforementioned configurations within the scope of matters described in the claims.

For example, in the above embodiments, the peripheral edge of the substrate 2 substantially coincides with the peripheral edge of the sealing resin 5 in plan view, but the present invention is not limited thereto, and, for example, the peripheral edge of the sealing resin 5 may, in plan view, be located on the inner side of the periphery of the substrate 2. In this case, the positional relationship between the piezoelectric vibrator 3 and the sealing resin 5 in plan view is based not on the lateral faces of the piezoelectric vibrator and the lateral faces of the substrate but on the lateral faces of the piezoelectric vibrator and the outer lateral faces of the sealing resin, and the shortest distance can be set as described with FIG. 11.

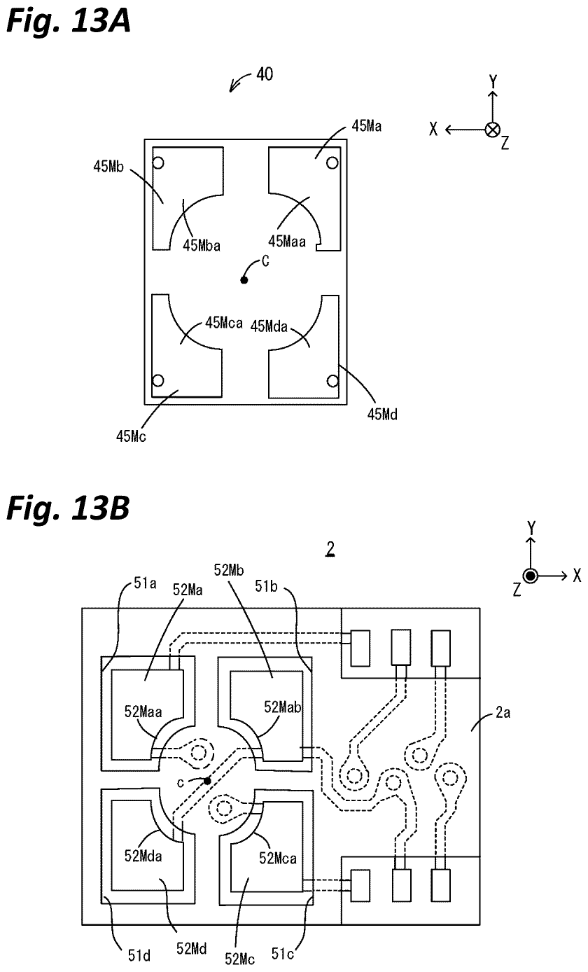

Also, in the above embodiments, the first to fourth external connection terminals 45a to 45d formed on the lower surface 40b of the second sealing member 40 (outer bottom surface of piezoelectric vibrator 3) have, in plan view, a substantially L shape that bends such that the edges 45aa to 45da nearest the center C extend away from the center C, but the present invention is not limited thereto, and, for example, each of the first to fourth external connection terminals formed on the lower surface 40b of the second sealing member 40 (outer bottom surface of the piezoelectric vibrator 3) may, in plan view, have another shape whose edge nearest the center C extend away from the center C. For example, as shown in FIG. 13(a), first to fourth external connection terminals 45Ma to 45Md may, in plan view, be formed such that edges 45Maa to 45Mda nearest the center C curve so as to extend away from the center C. In this case, as shown in FIG. 13(b), first to fourth piezoelectric vibrator mounting pads 52Ma to 52Md formed on the upper surface 2a of the substrate 2 are, in plan view, formed such that edges 52Maa to 52Mda nearest the center C (center of overlapping region on upper surface 2a of substrate 2 where upper surface 2a of substrate 2 and piezoelectric vibrator 3 overlap in plan view) of the first to fourth piezoelectric vibrator mounting pads 52Ma to 52Md curve so as to extend away from the center C. The first to fourth piezoelectric vibrator mounting pads 52Ma to 52Md each have, in plan view, an analogous shape or a similar shape to the external connection terminal to be joined thereto, among the first to fourth external connection terminals 45Ma to 45Md. Note that the relationship whereby the piezoelectric vibrator mounting pad has a similar shape to the external connection terminal is also satisfied in cases such as where the piezoelectric vibrator mounting pad and a figure the same as the external connection terminal or obtained by enlarging or reducing the external connection terminal (figure has an analogous shape to external connection terminal) (1) differ in the ratio of the two sides of the external connection terminal and the ratio of the two sides of the piezoelectric vibrator mounting pad, (2) differ regarding the presence or absence of chamfers, the position or size of chamfers, or the like, (3) differ regarding the presence or absence of protruding parts or recessed parts, the position or size of protruding parts or recessed parts, or the like, or (4) differ regarding the curvature of curved edges. Note that these examples are merely given as examples of similar shapes, and the similar shapes are not intended to be limited thereto.

In the above embodiments, the first to fourth piezoelectric vibrator mounting pads 52a to 52d all have, in plan view, an analogous shape or a similar shape to the external connection terminal to be joined thereto, among the first to fourth external connection terminals 45a to 45d, but the present invention is not limited thereto, and a configuration need only be adopted in which at least one of the first to fourth piezoelectric vibrator mounting pads 52a to 52d has, in plan view, an analogous shape or a similar shape to the external connection terminal to be joined thereto, among the first to fourth external connection terminals 45a to 45d.

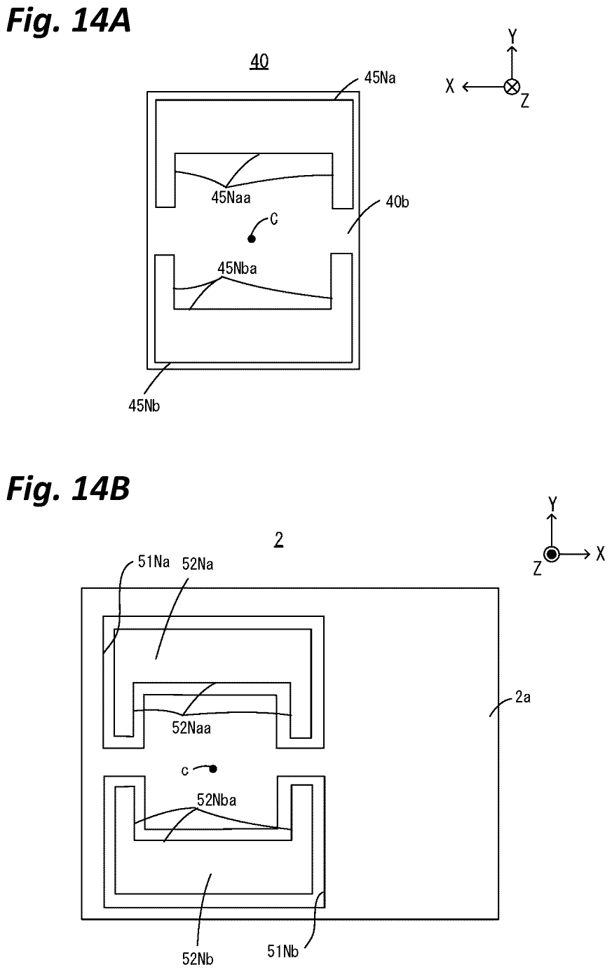

Also, in the above embodiments, four external connection terminals are formed on the outer bottom surface of the piezoelectric vibrator 3 (lower surface 40b of second sealing member 40), namely, the first to fourth external connection terminals 45a to 45d, and four piezoelectric vibrator mounting pads are formed on the upper surface 2a of the substrate 2, namely, the first to fourth piezoelectric vibrator mounting pads 52a to 52d, but the present invention is not limited thereto, and other numbers of external connection terminals and piezoelectric vibrator mounting pads may be provided, such as shown in FIG. 14(a) and 14(b), in which there are two external connection terminals, namely, first and second external connection terminals 45Na and 45Nb, and two piezoelectric vibrator mounting pads, namely, first and second piezoelectric vibrator mounting pads 52Na and 52Nb. Note that, in FIG. 14(a), illustration of the through-hole electrodes and the like other than the first and second external connection terminals 45Na and 45Nb is omitted for the sake of simplifying the diagram, and that, in FIG. 14(b), illustration of the pads, wiring patterns, through-hole electrodes and the like other than the first and second piezoelectric vibrator mounting pads 52Na and 52Nb is omitted for the sake of simplifying the diagram.

As shown in FIG. 14(a), the first and second external connection terminals 45Na and 45Nb are formed in a peripheral portion of the lower surface 40b of the second sealing member 40, and, in plan view, have a U shape that bends such that edges 45Naa and 45Nba of the first and second external connection terminals 45Na and 45Nb nearest the center (center of lower surface 40b of second sealing member 40) C extend away from the center C. Also, the first and second piezoelectric vibrator mounting pads 52Na and 52Nb are respectively formed on the bottom surfaces of first and second recessed parts 51Na and 51Nb provided in the upper surface 2a of the substrate 2, and, in plan view, have a U shape that bends such that edges 52Naa and 52Nba of the first and second piezoelectric vibrator mounting pads 52Na and 52Nb nearest the center (center of overlapping region on upper surface 2a of substrate 2 where upper surface 2a of substrate 2 and piezoelectric vibrator 3 overlap) C extend away from the center C. The first and second piezoelectric vibrator mounting pads 52Na and 52Nb each have, in plan view, an analogous shape or a similar shape to the external connection terminal to be joined thereto, among the first and second external connection terminals 45Na and 45Nb.

Also, in the above embodiments, the piezoelectric vibrator 3 has a structure in which the piezoelectric diaphragm 10, the first sealing member 30 covering the first excitation electrode 20 of the piezoelectric diaphragm 10, and the second sealing member 40 covering the second excitation electrode 25 of the piezoelectric diaphragm 10 are overlaid on each other, but the present invention is not limited thereto, and, for example, the piezoelectric vibrator may have a structure in which a quartz crystal piece is mounted on the inner side of the base of a box-shaped structure in cross-sectional view having a cavity opened only upward, and the opening is closed with a flat lid and airtightly sealed.

Also, in the above embodiments, the vibration part 11 of the piezoelectric diaphragm 10 may be, for example, a vibration part having a flat shape, a vibration part having a mesa structure (structure in which central portion is thicker than outer peripheral portions), or a vibration part having an inverted mesa structure (structure in which central portion is thinner than outer peripheral portions).

Also, in the above embodiments, the shape of the vibration part 11 of the piezoelectric diaphragm 10 is, for example, a rectangle (AT-cut), but is not limited thereto, and may, for example, be a rectangle (SC-cut, etc.) or a tuning fork shape (BT-cut).

Also, the electronic components 4, 4A, 4B, 4C, and 4D may be an IC that includes a temperature compensation circuit.

Also, the above embodiments and variations are applicable to both a SPXO (Simple Packaged Crystal Oscillator) and a TCXO (Temperature Compensated Crystal Oscillator).

Also, the contents described in the above embodiments and the contents described in the above variations may be combined as appropriate.

### INDUSTRIAL APPLICABILITY

The present invention is widely applicable to piezoelectric vibration devices that include a substrate, a piezoelectric vibrator and an electronic component mounted to one main surface of the substrate, and a sealing resin molded on the one main surface side of the substrate so as to cover the piezoelectric vibrator and the electronic component.

### DESCRIPTION OF REFERENCE MARKS

1, 1A, 1B, 1C, 1D Piezoelectric vibration device
2, 2A, 2B, 2C, 2D Substrate
3, 3A, 3B, 3C, 3D Piezoelectric vibrator
4, 4A, 4B, 4C, 4D Electronic component
5, 5A, 5B, 5C, 5D Sealing resin
45a-45d First to fourth external connection terminals
51a-51d First to fourth recessed parts
52a-52d First to fourth piezoelectric vibrator mounting pads

1. A piezoelectric vibration device comprising:
a substrate;
a piezoelectric vibrator and an electronic component mounted to one main surface of the substrate; and
a sealing resin molded on the one main surface side of the substrate so as to cover the piezoelectric vibrator and the electronic component; wherein
on an outer bottom surface of the piezoelectric vibrator, a plurality of external connection terminals are formed in a peripheral portion of the outer bottom surface,
on the one main surface of the substrate, a plurality of piezoelectric vibrator mounting pads respectively corresponding to the plurality of external connection terminals are formed,
each of the plurality of external connection terminals is joined via solder to a corresponding piezoelectric vibrator mounting pad among the plurality of piezoelectric vibrator mounting pads, and
in plan view, sides constituting outer lateral faces of the sealing resin respectively oppose sides constituting lateral faces of the piezoelectric vibrator, and a shortest distance among the distances between the opposing sides of the outer lateral faces of the sealing resin and the lateral faces of the piezoelectric vibrator is 7.8% or more of a dimension of the sealing resin in a length direction of the shortest distance.

2. The piezoelectric vibration device according to claim 1, wherein:
the substrate has a substantially rectangular shape in plan view,
the piezoelectric vibrator has a substantially rectangular shape in plan view, and
the piezoelectric vibrator is mounted to the one main surface of the substrate such that short sides of the piezoelectric vibrator are orthogonal to short sides of the substrate.

3. The piezoelectric vibration device according to claim 1, wherein:
the plurality of piezoelectric vibrator mounting pads are four piezoelectric vibrator mounting pads, and are respectively disposed in four corners of a substantially rectangular region that includes an overlapping region, on the one main surface of the substrate, where the one main surface and the piezoelectric vibrator overlap each other in plan view and surrounds the overlapping region,
each of the plurality of piezoelectric vibrator mounting pads is substantially L-shaped in plan view, and
each of the piezoelectric vibrator mounting pads bends such that an edge nearest a center of the overlapping region, among the edges of the piezoelectric vibrator mounting pad, extends away from the center in plan view.

4. The piezoelectric vibration device according to claim 1, wherein each of the plurality of piezoelectric vibrator mounting pads is located inside a recessed part provided in the one main surface of the substrate to correspond to the piezoelectric vibrator mounting pad, and disposed such that there is a gap between the opposing lateral faces of the piezoelectric vibrator mounting pad and the recessed part.

5. The piezoelectric vibration device according to claim 2, wherein:
the plurality of piezoelectric vibrator mounting pads are four piezoelectric vibrator mounting pads, and are respectively disposed in four corners of a substantially rectangular region that includes an overlapping region, on the one main surface of the substrate, where the one main surface and the piezoelectric vibrator overlap each other in plan view and surrounds the overlapping region,
each of the plurality of piezoelectric vibrator mounting pads is substantially L-shaped in plan view, and
each of the piezoelectric vibrator mounting pads bends such that an edge nearest a center of the overlapping region, among the edges of the piezoelectric vibrator mounting pad, extends away from the center in plan view.

6. The piezoelectric vibration device according to claim 2, wherein each of the plurality of piezoelectric vibrator mounting pads is located inside a recessed part provided in the one main surface of the substrate to correspond to the piezoelectric vibrator mounting pad, and disposed such that there is a gap between the opposing lateral faces of the piezoelectric vibrator mounting pad and the recessed part.
